(19) United States
(12) Patent Application Publication
(10) Pub. No.: US 2022/0165925 A1
(43) Pub. Date: May 26, 2022

(54) MICRO-LED UV RADIATION SOURCE AND METHOD FOR MANUFACTURING SAME

(71) Applicant: SAKAI DISPLAY PRODUCTS CORPORATION, Sakai City, Osaka (JP)

(72) Inventor: KATSUHIKO KISHIMOTO, Sakai-shi, Osaka (JP)

(21) Appl. No.: 17/440,988

(22) PCT Filed: Mar. 22, 2019
(86) PCT No.: PCT/JP2019/012154

§ 371 Date: Sep. 20, 2021

(51) Int. Cl. H01L 33/60; H01L 25/075; H01L 33/62; H01L 33/00

(52) U.S. Cl. CPC H01L 33/60; H01L 33/0093; H01L 33/62; H01L 25/0753

(57) ABSTRACT

A micro-LED ultraviolet radiation source of the present disclosure includes a crystal growth substrate (100) and a frontplane (200) that includes a plurality of micro-LEDs (220), each of which includes a first semiconductor layer (21) of a first conductivity type and a second semiconductor layer (22) of a second conductivity type, and a device isolation region (240) located between the micro-LEDs. The device isolation region includes at least one metal plug (24) electrically coupled with the second semiconductor layer. This μLED ultraviolet radiation source includes a middle layer (300) which includes first contact electrodes (31) electrically coupled with the first semiconductor layer and a second contact electrode (32) coupled with the metal plug, and a backplane (400) provided on the middle layer. The substrate, the frontplane, the middle layer and the backplane are divided into a plurality of light-emitting device units, and the plurality of light-emitting device units are supported by a flexible film.

### TECHNICAL FIELD

The present disclosure relates to a micro-LED ultraviolet radiation source and a production method thereof.

### BACKGROUND ART

A device has been proposed which uses, as a light source for radiating ultraviolet light, a deep-UV LED (Light Emitting Diode) in substitution for a fluorescent lamp and a mercury lamp.

Patent Document No. 1 discloses a sterilizer in which deep-UV LED groups arrayed on a metal heat dissipation plate are overmolded with a quartz glass package.

### CITATION LIST

### Patent Literature

Patent Document No. 1: Japanese Laid-Open Patent Publication No. 2015-91582

### SUMMARY OF INVENTION

### Technical Problem

It is difficult to mount a large number of deep-UV LEDs to, for example, a curved member.

The present disclosure provides a novel ultraviolet radiation source which can solve the above-described problem.

### Solution to Problem

A micro-LED ultraviolet radiation source of the present disclosure includes, in an exemplary embodiment: a crystal growth substrate; a frontplane on the crystal growth substrate, the frontplane including a plurality of micro-LEDs, each of which includes a first semiconductor layer of a first conductivity type and a second semiconductor layer of a second conductivity type and is capable of radiating ultraviolet light, and a device isolation region located between the plurality of micro-LEDs, the device isolation region including at least one metal plug electrically coupled with the second semiconductor layer; a middle layer supported by the frontplane, the middle layer including a plurality of first contact electrodes respectively electrically coupled with the first semiconductor layer of the plurality of micro-LEDs and at least one second contact electrode coupled with the metal plug; and a backplane supported by the middle layer, the backplane including an electric circuit electrically coupled with the plurality of micro-LEDs via the plurality of first contact electrodes and the at least one second contact electrode. The crystal growth substrate, the frontplane, the middle layer, and the backplane are divided into a plurality of light-emitting device units. Each of the plurality of light-emitting device units includes at least one of the plurality of micro-LEDs, and the ultraviolet light radiated from the plurality of micro-LEDs travels through the crystal growth substrate before going out of the micro-LED ultraviolet radiation source, and the plurality of light-emitting device units are supported by a flexible film.

In one embodiment, the backplane includes a layer of a metal, semiconductor, and/or insulative material deposited on the middle layer.

In one embodiment, the device isolation region includes a reflector capable of reflecting ultraviolet light radiated from each of the plurality of micro-LEDs such that the reflected ultraviolet light travels toward the crystal growth substrate.

In one embodiment, at least a reflecting surface of the reflector is made of aluminum (Al) or rhodium (Rh).

In one embodiment, a wavelength of the ultraviolet light is not less than 200 nm and not more than 390 nm.

In one embodiment, at least part of the at least one metal plug functions as the reflector.

In one embodiment, each of the plurality of micro-LEDs has a forwardly-tapered side surface, and the at least one metal plug is in contact with the side surface of each of the plurality of micro-LEDs.

In one embodiment, the crystal growth substrate is a sapphire substrate.

In one embodiment, the micro-LED ultraviolet radiation source further includes a member having a curved surface or a corner portion, wherein the flexible film is attached to the curved surface or the corner portion.

In one embodiment, the member includes a long axis portion having an inner surface and an outer surface, the long axis portion being elongated in a predetermined direction, and the flexible film is attached to the inner surface and/or the outer surface of the long axis portion.

In one embodiment, each of the plurality of light-emitting device units includes the plurality of micro-LEDs arrayed in the predetermined direction.

In one embodiment, the electric circuit includes a thin film transistor.

In one embodiment, in each of the plurality of light-emitting device units, the device isolation region of the frontplane includes an insulator covering a side surface of the plurality of micro-LEDs, the insulator having at least one through hole for the metal plug.

In one embodiment, the flexible film includes an interconnection layer for electrically coupling the backplane of the plurality of light-emitting device units.

A micro-LED ultraviolet radiation source production method of the present disclosure includes, in an exemplary embodiment: providing a multilayer stack which includes a crystal growth substrate, a frontplane supported by the crystal growth substrate, the frontplane including a plurality of micro-LDs, each of which includes a first semiconductor layer of a first conductivity type and a second semiconductor layer of a second conductivity type and is capable of radiating ultraviolet light, and a device isolation region located between the plurality of micro-LEDs, the device isolation region including at least one metal plug electrically coupled with the second semiconductor layer, and a middle layer supported by the frontplane, the middle layer including a plurality of first contact electrodes respectively electrically coupled with the first semiconductor layer of the plurality of micro-LEDs and at least one second contact electrode coupled with the metal plug; forming a backplane on the multilayer stack, the backplane including an electric circuit electrically coupled with the plurality of micro-LEDs via the plurality of first contact electrodes and the at least one second contact electrode; dividing the multilayer stack and the backplane into a plurality of light-emitting device units; and transferring the plurality of light-emitting device units to a flexible film.

In one embodiment, the transferring includes attaching an expandable film to the crystal growth substrate and expanding the expandable film, thereby enlarging a gap between the plurality of light-emitting device units, and attaching the plurality of light-emitting device units on the expanded expandable film to the flexible film.

In one embodiment, the transferring includes attaching an expandable film to the backplane and expanding the expandable film, thereby enlarging a gap between the plurality of light-emitting device units, and further attaching the expanded expandable film to a member having a curved surface or a corner portion while the plurality of light-emitting device units are kept attached to the expanded expandable film.

### Advantageous Effects of Invention

According to an embodiment of the present invention, a micro-LED ultraviolet radiation source is provided which can solve the previously-described problem.

### BRIEF DESCRIPTION OF DRAWINGS

FIG. 1A is a cross-sectional view showing part of a μLED UV source 1000 according to an embodiment of the present disclosure.

FIG. 1B is a plan view showing an arrangement example of μLEDs 220 in the ρLED UV source 1000.

FIG. 2 is a cross-sectional view showing another configuration example of the frontplane in the μLED UV source 1000.

FIG. 3 is a cross-sectional view showing still another configuration example of the frontplane in the ρLED LUV source 1000.

FIG. 4A is a cross-sectional view schematically showing reflection of ultraviolet light by a metal plug 24.

FIG. 4B is another cross-sectional view schematically showing reflection of ultraviolet light by a metal plug 24.

FIG. 4C provides graphs showing the relationship between the reflectance of a reflector metal and the wavelength in an embodiment of the present disclosure.

FIG. 4D provides graphs showing the relationship between the reflectance of a reflector metal and the wavelength in an embodiment of the present disclosure.

FIG. 5 is a perspective view showing an example where the side surface 220S is formed by a lateral surface of a truncated cone.

FIG. 6 is a cross-sectional view showing still another configuration example of the μLED UV source 1000.

FIG. 7 is a cross-sectional view showing still another configuration example of the PLED LV source 1000.

FIG. 8 is a perspective view showing an arrangement example of the first contact electrodes 31 and the second contact electrodes 32 in the ρLED UV source 1000.

FIG. 9 is a circuit diagram showing an example of part of an electric circuit in the ρLED UV source 1000.

FIG. 10A is a perspective view schematically showing a production step of the μLED UV source 1000.

FIG. 102 is a perspective view schematically showing a production step of the μLED UV source 1000.

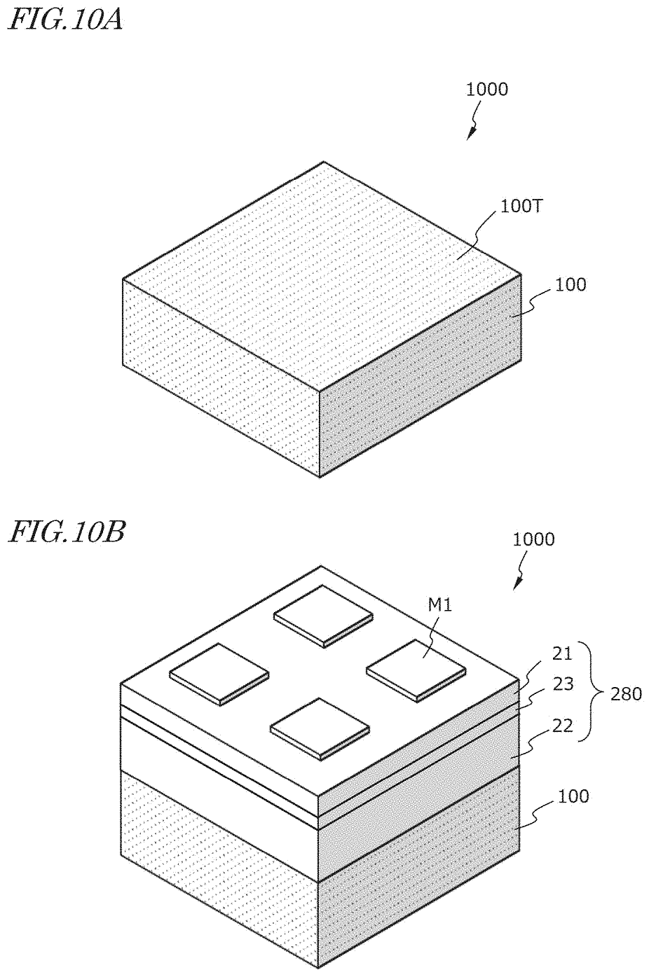

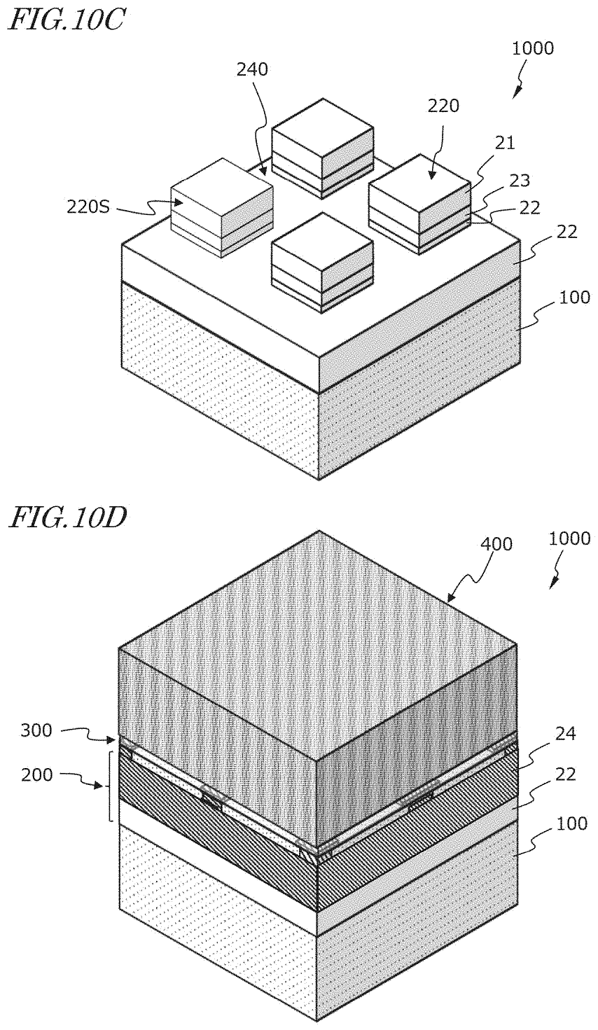

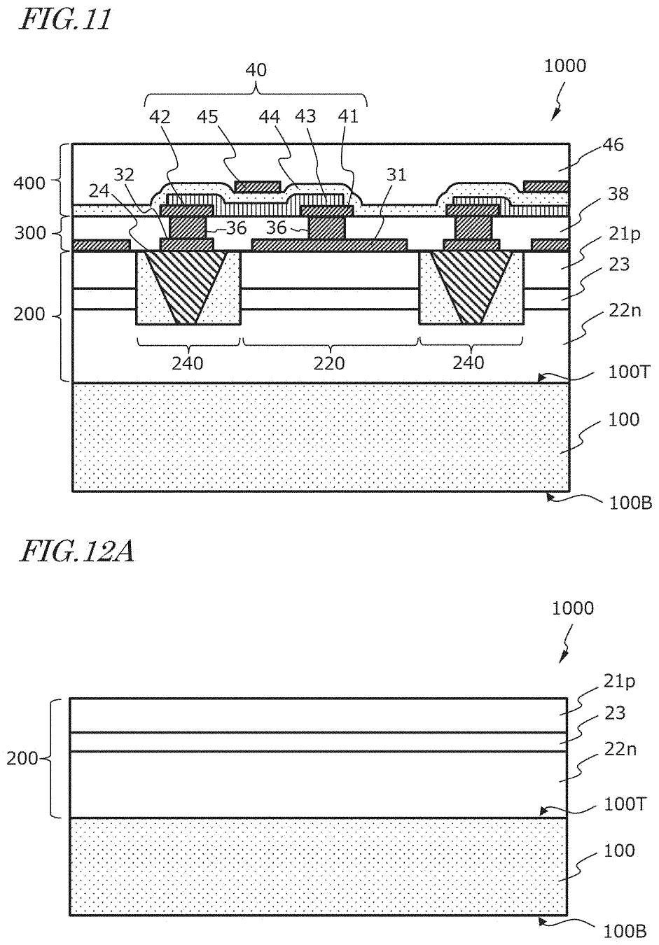

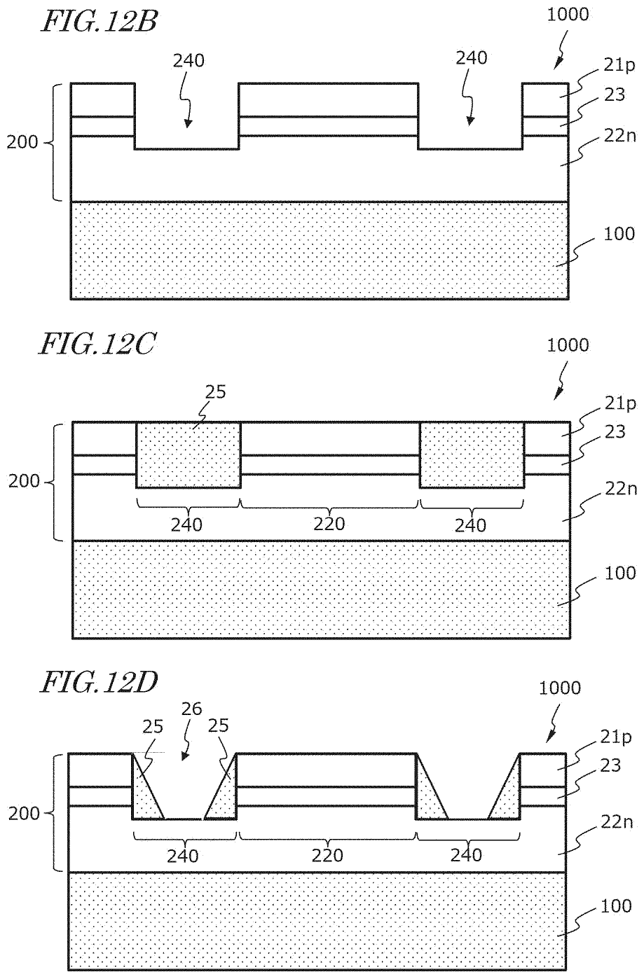

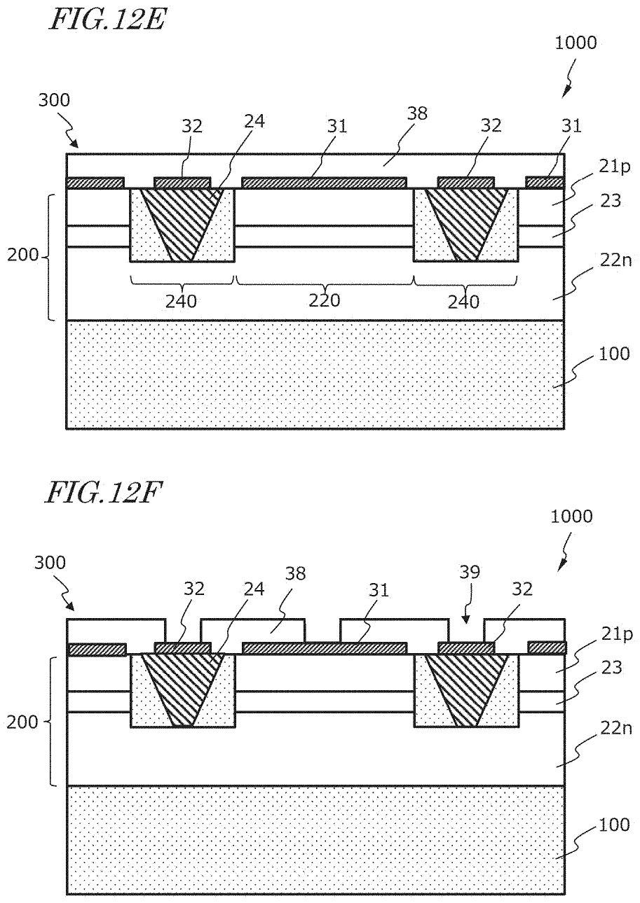

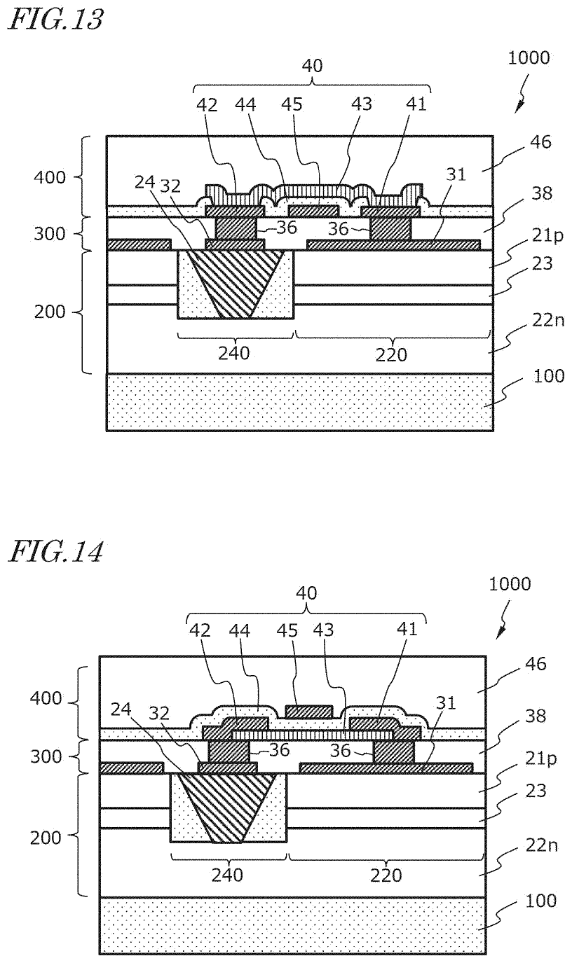

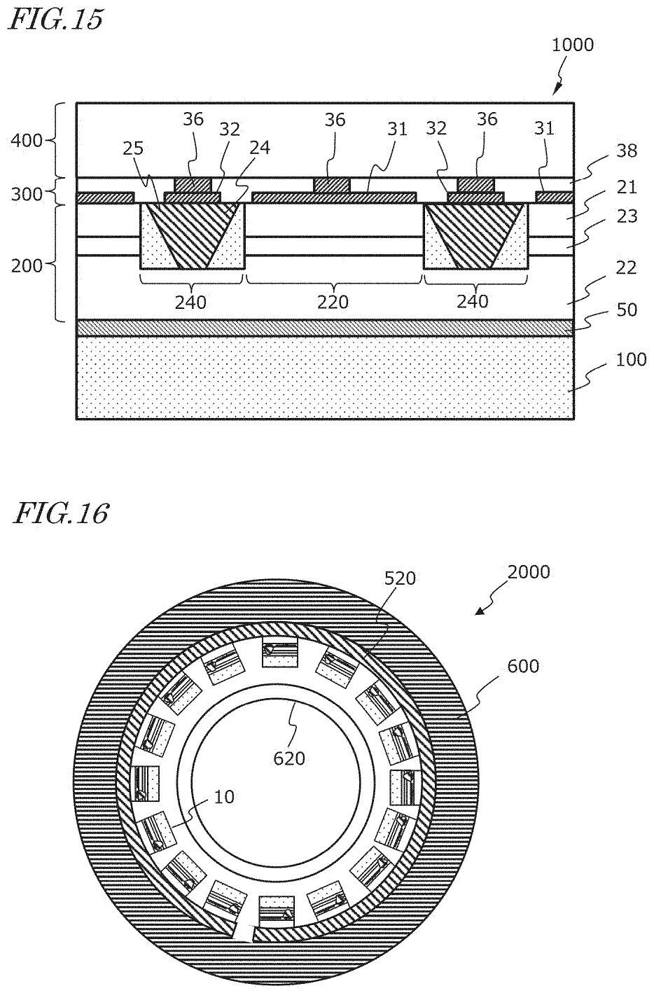

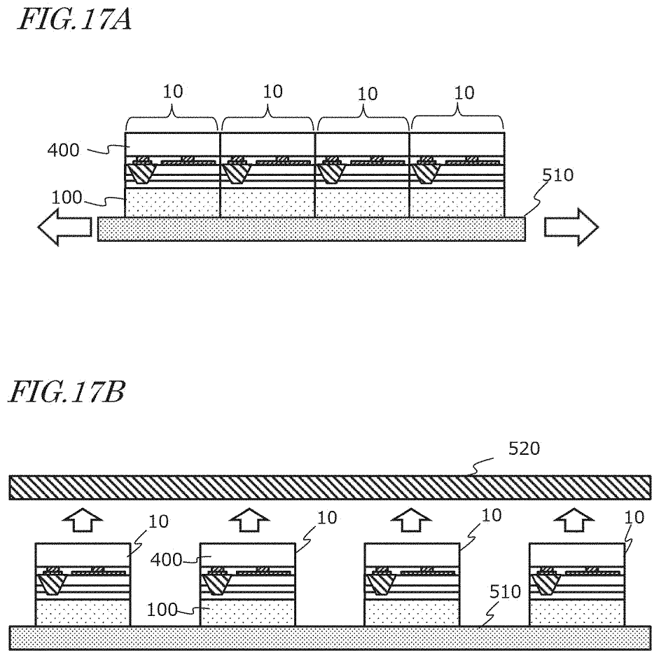

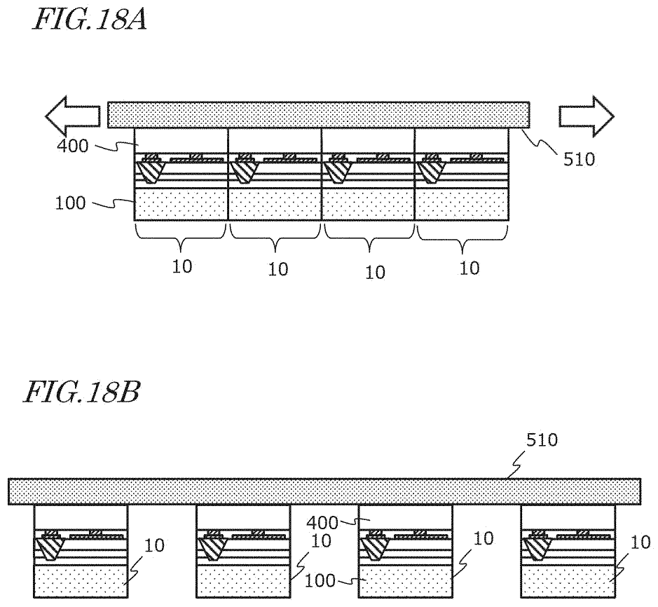

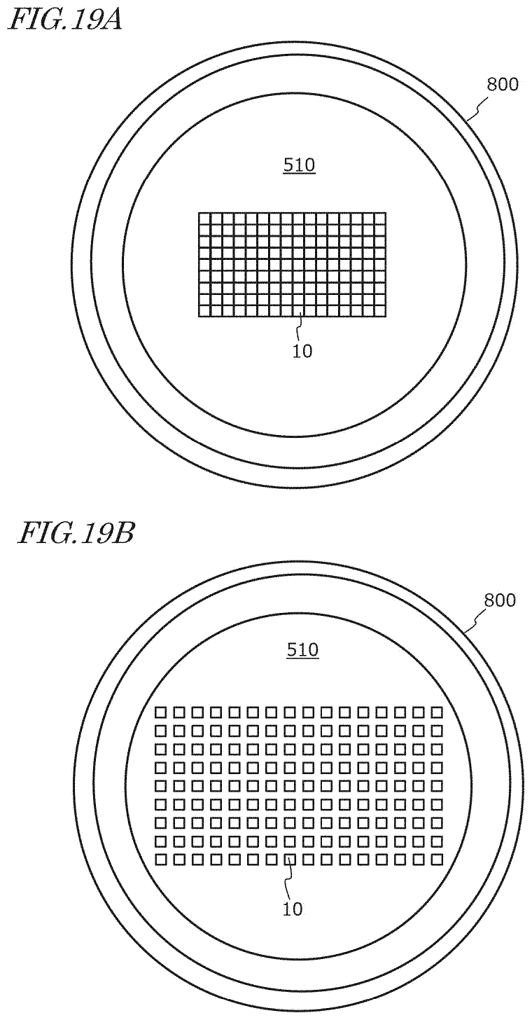

FIG. 10C is a perspective view schematically showing a production step of the μLED UV source 1000.

FIG. 10D is a perspective view schematically showing a production step of the μLED UV source 1000.

FIG. 11 is a cross-sectional view of the μLED UA source 1000 in an embodiment of the present disclosure.

FIG. 12A is a cross-sectional view schematically showing a production step of the μLED UV source 1000.

FIG. 12B is a cross-sectional view schematically showing a production step of the μLED UV source 1000.

FIG. 12C is a cross-sectional view schematically showing a production step of the μLED UV source 1000.

FIG. 12D is a cross-sectional view schematically showing a production step of the μLED UV source 1000.

FIG. 12E is a cross-sectional view schematically showing a production step of the μLED UV source 1000.

FIG. 12F is a cross-sectional view schematically showing a production step of the μLED UV source 1000.

FIG. 13 is a cross-sectional view showing another configuration example of the μLED UV source 1000 in an embodiment of the present disclosure.

FIG. 14 is a cross-sectional view showing still another configuration example of the μLED UV source 1000 in an embodiment of the present disclosure.

FIG. 15 is a cross-sectional view showing still another configuration example of the μLED UV source 1000 in an embodiment of the present disclosure.

FIG. 16 is a cross-sectional view showing a configuration example of a μLED UV source 2000 in an embodiment of the present disclosure.

FIG. 17A is a cross-sectional view schematically showing a production step of the μLED UV source 2000.

FIG. 17B is a cross-sectional view schematically showing a production step of the μLED UV source 2000.

FIG. 19A is a cross-sectional view schematically showing a production step of the μLED UV source 2000.

FIG. 18B is a cross-sectional view schematically showing a production step of the μLED UV source 2000.

FIG. 19A is a plan view schematically showing a production step of the μLED UV source 2000.

FIG. 19B is a plan view schematically showing a production step of the μLED UV source 2000.

### DESCRIPTION OF EMBODIMENTS

### Definitions

In the present disclosure, “micro-LED” means a light emitting diode (LEG) whose occupation region can be included within an area of 1000 μm×1000 μm or within a stripe region of not more than 1000 μm in width. In the present disclosure, the electromagnetic wave radiated by the micro-LED is ultraviolet light at the wavelength of not more than 380 nm. Hereinafter, “micro-LED” is also referred to as “μLED”.

μLEDs have a first semiconductor layer of the first conductivity type and a second semiconductor layer of the second conductivity type. The first conductivity type is one of p-type and n-type. The second conductivity type is the other of p-type and n-type. For example, if the first conductivity type is p-type, the second conductivity type is n-type. If, on the contrary, the first conductivity type is n-type, the second conductivity type is p-type. Each of the first semiconductor layer and the second semiconductor layer can have a single-layer structure or a multilayer structure. Typically, an emission layer which has at least one quantum well (or double heterostructure) is provided between the first semiconductor layer and the second semiconductor layer.

In the present disclosure, “micro-LED ultraviolet radiation source (μLED UV source)” refers to a device which includes a plurality of μLEDs each capable of radiating ultraviolet light. The plurality of μLEDs in the μLED UV source are also referred to as “PLED array”. The PLED UV source can be used in various uses which require irradiation with ultraviolet light, including curing of a resin with ultraviolet light, exposure of a resist to light, and sterilization. Particularly, the μLED LV source of the present disclosure can realize an arbitrary irradiation pattern in a maskless lithography.

<Basic Configuration>

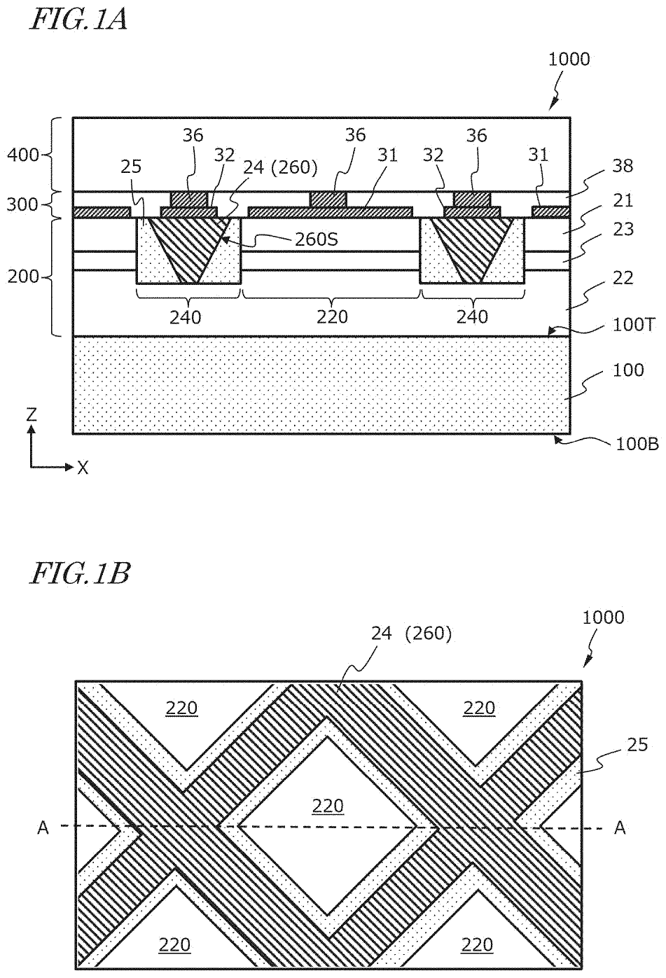

A basic configuration example of a μLED UV source of the present disclosure is described with reference to FIG. 1A and FIG. 1B. FIG. 1A is a cross-sectional view showing part of a μLED UV source 1000. FIG. 1B is a plan view showing an arrangement example of a μLED array in the μLED UV source 1000. The cross section of the μLED UV source 1000 shown in FIG. 1A is identical with the cross section taken along line A-A of FIG. 1B.

The μLED UV source 1000 can include a large number of μLEDs, for example, several hundreds to several thousands, or more than 10,000. FIG. 1A and FIG. 1B show only a part of the μLED UV source 1000 which includes several μLEDs. The entirety of the μLED UV source 1000 has a configuration where the shown part is, for example, periodically repeated or repeated in a particular pattern.

In the μLED UV source 1000, ultraviolet light is radiated from a plurality of μLEDs divided into small pieces rather than radiated from a single continuous emission layer included in a conventional, single large LED device. Due to this feature, how to use ultraviolet radiation from the end face of the emission layer included in each μLED is important. This is because, as the size of the μLEDs decreases and the number of μLEDs included in the μLED UV source 1000 increases, the proportion of the area of the end face of the emission layer to an area of the emission layer which is perpendicular to the layer-stacking direction of semiconductor layers increases. In an embodiment of the present disclosure, a reflector which will be described later is provided in a region between respective μLEDs (device isolation region) such that ultraviolet light radiated in a horizontal direction from the emission layer can also be effectively used.

The μLED UV source 1000 includes a crystal growth substrate 100, a frontplane 200 supported by the crystal growth substrate 100, a middle layer 300 supported by the frontplane 200, and a backplane 400 supported by the middle layer.

In the attached drawings, the proportion of the transverse size to the longitudinal size of respective components such as μLEDs is not necessarily equal to the actual proportion in an embodiment. In the drawings, clarity takes precedence in determining the proportion of the depicted components. The orientation of respective components in the drawings does not limit at all the orientation in actual production of the μLED UV source and the orientation in actual use of the μLED UV source. In FIG. 1A and FIG. 1B, a coordinate system of X-axis, Y-axis and Z-axis, which are mutually orthogonal, is shown for reference.

<Crystal Growth Substrate>

The crystal growth substrate 100 is a substrate on which semiconductor crystals, which are constituents of the μLEDs, are to epitaxially grow. In the present disclosure, the crystal growth substrate 100 is a sapphire substrate. Hereinafter, the crystal growth substrate 100 that is made of sapphire is simply referred to as “substrate”. A surface 100T of the substrate 100 on which crystal growth occurs is referred to as “upper surface” or “crystal growth surface”. Another surface 100B of the substrate 100 which is opposite to the surface 100T is referred to as “lower surface”. In this specification, the terms “upper surface” and “lower surface” do not depend on the actual orientation of the substrate 100 when they are used.

A typical example of semiconductor crystals which can be used in embodiments of the present disclosure is a gallium nitride based compound semiconductor. Hereinafter, the gallium nitride based compound semiconductor is also referred to as “GaN”. Some of gallium (Ga) atoms in GaN may be substituted with aluminum (Al) atoms or indium (In) atoms. GaN in which some of Ga atoms are substituted with Al atoms is also referred to as “AlGaN”. GaN in which some of Ga atoms are substituted with In atoms is also referred to as “InGaN”. GaN in which some of Ga atoms are substituted with Al atoms and In atoms is also referred to as “AlInGaN” or “InAlGaN”. The bandgap of GaN is smaller than the bandgap of AlGaN but greater than the bandgap of InGaN. In the present disclosure, gallium nitride based compound semiconductors in which some of constituent atoms are substituted with other atoms are also generically referred to as “GaN”. “GaN” can be doped with an n-type impurity and/or a p-type impurity as impurity ion. GaN whose conductivity type is n-type is referred to as “n-GaN”. GaN whose conductivity type is p-type is referred to as “p-GaN”. Details of the method of growing semiconductor crystals will be described later. In the embodiments of the present disclosure, semiconductor crystals which are constituents of the μLED are not limited to GaN-based semiconductors but may be made of a nitride semiconductor such as AlN, InN, or AlInN, or any other type of semiconductor.

In an embodiment of the present disclosure, the substrate 100 is a constituent of a final μLED UV source 1000. The thickness of the substrate 100 can be, for example, not less than 30 μm and not more than 1000 μm, preferably not more than 500 μm. The roles of the substrate 100 are the base for crystal growth and the optical member for improving the ultraviolet light extraction efficiency during operation. To these ends, the rigidity of the μLED UV source 1000 may be compensated for with any other rigid member than the substrate 100. Such a rigid member can be fixed to the backplane 400, for example. During the production process, a supporting substrate (not shown) for compensating for the rigidity of the substrate 100 may be secured to the lower surface 1005 of the substrate 100. Such a supporting substrate may be removed from a final μLED UV source 1000.

The upper surface (crystal growth surface) 100T of the substrate 100 may have a structure for relieving the crystal lattice mismatch, such as grooves or ridges. Also, a buffer layer for reducing the crystal lattice mismatch may be provided at the upper surface 100T of the substrate 100. The lower surface 1005 of the substrate 100 may have microscopic irregularities for further improving the extraction efficiency of ultraviolet light radiated from a μLED array and then transmitted through the substrate 100 or for diffusing the ultraviolet light. Examples of the microscopic irregularities include a moth-eye structure. The moth-eye structure continuously changes the effective refractive index across the lower surface 1008 of the substrate 100 and, therefore, the proportion of light reflected by the lower surface 1008 of the substrate 100 to the inside of the substrate 100 (reflectance can be greatly reduced (to substantially zero).

In the present disclosure, the positive direction of Z axis shown in FIG. 1A (the direction of the arrow) is also referred to as “crystal growth direction” or “semiconductor layering direction”. The lower surface 1005 and the upper surface 100T of the substrate 100 may be referred to as “front surface” and “rear surface”, respectively, of the substrate 100.

<Frontplane>

The frontplane 200 includes a plurality of μLEDs 220 and a device isolation region 240 located between the plurality of μLEDs 220. The plurality of μLEDs 220 can be arrayed in rows and columns in a two-dimensional plane (XY plane) which is parallel to the upper surface 100T of the substrate 100. Each of the plurality of μLEDs 220 includes a first semiconductor layer 21 of the first conductivity type and a second semiconductor layer 22 of the second conductivity type as shown in FIG. 1A. The second semiconductor layer 22 is closer to the substrate 100 than the first semiconductor layer 21.

In an embodiment of the present disclosure, each of the μLEDs 220 includes an emission layer 23 which can emit light independently of the other μLEDs 220. The emission layer 23 is present between the first semiconductor layer 21 and the second semiconductor layer 22. The device isolation region 240 includes at least one metal plug 24 electrically coupled with the second semiconductor layer 22. The metal plug 24 functions as a substrate-side electrode of the μLEDs 220.

A typical example of the first semiconductor layer 21 of the first conductivity type is a p-GaN layer. A typical example of the second semiconductor layer 22 of the second conductivity type is an n-GaN layer. Each of the p-GaN layer and the n-GaN layer does not need to have a homogeneous composition along a direction perpendicular to the upper surface 100T of the substrate 100 (semiconductor layering direction: positive direction of Z axis) but can have a multilayer structure. As previously described, Ga of GaN can be at least partially substituted with Al and/or In. Such substitution can be carried out for adjusting the bandgap and/or the refractive index of GaN. The concentration of the n-type impurity and the p-type impurity, i.e., the doping level, also does not need to be constant along the semiconductor layering direction (positive direction of Z axis).

A typical example of the emission layer 23 includes at least one AlGaN or InAlGaN well layer for emitting ultraviolet light. When the emission layer 23 includes a plurality of well layers, a barrier layer which has a greater bandgap than the well layer can be provided between the respective well layers. The bandgap of the well layer defines the emission wavelength. Specifically, λ×Eg=1240 holds where λ [nm] is the emission wavelength in vacuum and Eg [electron volt: eV] is the bandgap. Therefore, for example, ultraviolet light at λ=350 nm can be radiated by adjusting the bandgap Eg of the well layer to about 3.54 eV. For example, the bandgap of the AlGaN well layer can be adjusted according to the Al molar fraction in the AlGaN well layer.

Each of the plurality of semiconductor layers which are constituents of each μLED 220 is a monocrystalline layer epitaxially grown on the substrate 100 (epitaxial layer). The device isolation region 240 is defined by a trench-like recessed portion (hereinafter, referred to as “trench”) which is formed by partially etching the plurality of semiconductor layers epitaxially grown on the substrate 100. The occupation region of each of the μLEDs 220 isolated by the trench has a size which can be included within an area of 1000 μm×1000 μm (e.g., area of 100 μm×100 μm or smaller). The occupation region of the μLED 220 is defined by the contour of the first semiconductor layer 21 and/or the emission layer 23 demarcated by the device isolation region 240.

As shown in FIG. 10, the device isolation region 240 surrounds each of the μLEDs 220 and isolates each of the μLEDs 220 from the other μLEDs 220. More specifically, the device isolation region 240 electrically and spatially isolate the first semiconductor layer 21 and the emission layer 23 of each of the μLEDs 220 from the first semiconductor layer 21 and the emission layer 23 of the other μLEDs 220.

As shown in FIG. 1A, the second semiconductor layer 22 does not need to be completely isolated in each of the μLEDs 220. In the example shown in FIG. 1A, the second semiconductor layer 22 included in respective ones of the plurality of μLEDs 220 is formed by a single continuous semiconductor layer and is shared among the plurality of μLEDs 220. When the single continuous second semiconductor layer 22 is shared among the plurality of μLEDs 220, this second semiconductor layer 22 functions as a common electrode on the second conductivity side for the plurality of μLEDs 220. If the second semiconductor layers 22 of respective ones of the μLEDs 220 are mutually isolated and each of the second semiconductor layers 22 is coupled with an electrode (interconnection) on the second conductivity side at the backplane 400, occurrence of a disconnection failure in some of the electrodes or interconnections on the second conductivity side will cause an electrical communication failure in some of the μLEDs 220. However, when the second semiconductor layers 22 of respective ones of the plurality of μLEDs 220 are formed by a single continuous semiconductor layer, occurrence of such a failure can be suppressed. Embodiments of the present disclosure are not limited to such an example. The second semiconductor layer 22 of each of the μLEDs 220 may be isolated from the second semiconductor layers 22 of the other μLEDs 220 so long as it is appropriately coupled with a metal plug 24 or a TiN buffer layer which will be described later.

In this example, the device isolation region 240 includes an embedded insulator 25 which fills the gap between the plurality of μLEDs 220. The embedded insulator 25 has one or a plurality of through holes for the metal plugs 24. The through holes are filled with the metal material which forms the metal plugs 24. The metal plugs 24 may have a structure formed by stacking layers of different metals.

In an embodiment of the present disclosure, the upper surface of the frontplane 200 is preferably planarized as shown in FIG. 1A. Such planarization is realized by making the level of the upper surfaces of the metal plug 24 and the embedded insulator 25 in the device isolation region 240 generally coincident with the level of the upper surface of the first semiconductor layer 21 in the μLEDs 220.

<Reflector>

In an embodiment of the present disclosure, the device isolation region 240 of the μLED UV source 1000 includes a reflector 260 which is capable of reflecting ultraviolet light radiated from each of the plurality of μLEDs 220 such that the reflected ultraviolet light travels toward the crystal growth substrate 100. More specifically, the device isolation region 240 includes an embedded insulator 25 which ills the gap between the plurality of μLEDs 220. The embedded insulator 25 has a V-shape trench (through hole) for the metal plug 24. The embedded insulator 25 is made of a material which is capable of transmitting ultraviolet light radiated from the μLED 220.

The metal plug 24 is in contact with the second semiconductor layer 22 at the bottom of the V-shape trench. This metal plug 24 not only functions as a conductor for electrically coupling each of the μLEDs 220 with the backplane 400 but also functions as the reflector 260. As shown in the drawing, the side surface (reflecting surface 260S) of the metal plug 24 is not perpendicular to, but inclined with respect to, the upper surface 100T of the crystal growth substrate 100. It is desirable that at least part of the metal plug 24 which is in contact with the second semiconductor layer 22 is made of a material which can realize an ohmic contact. However, the other part can be made of various metal materials. For example, it can be made of at least one type of metal selected from the group consisting of Al, Ag, Rh, Au, Cu, Pd, Pt, Ti, Ni, Mo, and W. According to the research by the present inventor, from the viewpoint of reflecting ultraviolet light radiated from the μLED 220 with high reflectance (e.g., 90% or higher), it is desirable that at least the side surface of the metal plug 24 (the reflecting surface 2603 of the reflector 260) is made of Al. When the reflectance of 70% or higher is to be secured as a practical reflectance, it is preferred that the reflecting surface 260S of the reflector 260 is made of Al, Ag, or Rh. Particularly for ultraviolet light at the wavelength of not more than 300 nm, it is desirable that the reflecting surface 260S of the reflector 260 is made of Al or Rh. As a result of simulations which will be described later, it was found that for example the reflectance for ultraviolet light at the wavelength of 350 nm has the relationship of Al>Ag>Rh>>Cu≈Ti. The reflectance for ultraviolet light at the wavelength of not more than 300 nm has the relationship of Al>Rh>>Ti>Cu>Ag.

The metal plug 24, which functions as the reflector 260, surrounds each of the μLEDs 220 as shown in FIG. 1B. Therefore, ultraviolet light radiated in all directions from the μLED 220 is reflected by the inclined side surface (reflecting surface 260S) of the metal plug 24 in a direction toward the crystal growth substrate 100. The metal plug 24 does not need to be a single electrical conductor which has a grid shape but may be separated into a plurality of parts.

<Other Forms of Reflector>

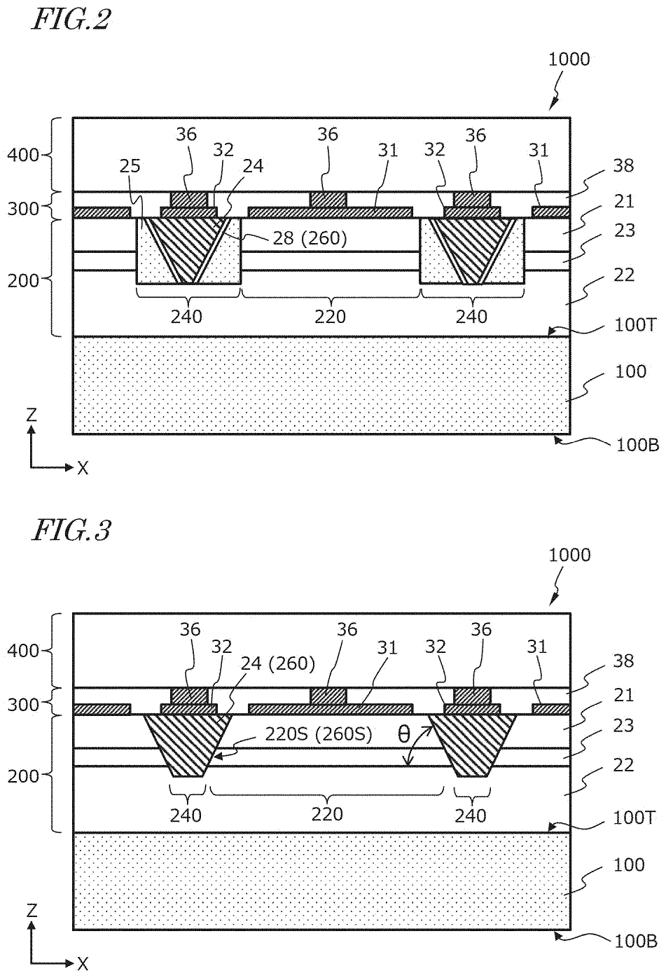

Next, refer to FIG. 2. In the example shown in FIG. 2, the metal plug 24 includes a reflecting layer 28 over the side surface. The reflecting layer 28 functions as the reflector 260. The reflecting layer 28 can be made of a different material from that of the metal plug 24, for example, Al or Rh. The thickness of the reflecting layer 28 is, for example, not less than 30 nm and not more than 50 nm. The reflecting layer 28 may be made of a non-metal material. The reflecting layer 29 can be made of, for example, a dielectric material which has a different refractive index from that of the embedded insulator 25. The difference in refractive index at the interface between the reflecting layer 28 and the embedded insulator 25 can realize reflection of ultraviolet light radiated from the μLED 220. Ultraviolet light which has been transmitted through this interface so as to arrive at the metal plug 24 can be reflected by the metal plug 24 itself.

FIG. 3 is a cross-sectional view showing another configuration example of the μLED UV source 1000. In this example, each of the plurality of μLEDs 220 has an inclined side surface 220S. The metal plug 24 is in contact with the side surface 220S of each of the μLEDs 220. In this example, the metal plug 24 has a reflecting surface 260S which is in contact with the side surface 220S of each of the μLEDs 220 and functions as the reflector 260. In this example, the inclination angle θ of the reflecting surface 260S defines the inclination angle of the side surface 220S of each of the μLEDs 220. In the example shown in FIG. 3, the inclination angle θ of the reflecting surface 260S is smaller than 90° (e.g., 30-60°). The side surface 220S of the μLED 220 forms a forward taper.

The surface of the metal plug 24 is preferably made of a material which can realize an ohmic contact with the second semiconductor layer 22. When the second semiconductor layer 22 is made of n-GaN, a metal which has a smaller work function Φm than the work function Φn of the n-GaN (for example, Ti) is used, whereby a selective ohmic contact is realized between the second semiconductor layer 22 and the metal plug 24 and, meanwhile, a high-resistance layer can be formed between the first semiconductor layer 21 that is made of p-GaN and the metal plug 24. According to the configuration example of FIG. 3, the step of forming the embedded insulator 25 in the device isolation region 240 and the step of forming a through hole in the embedded insulator 25 can be omitted.

In the configuration example of FIG. 3, the configuration of the metal plug 24 is not limited to the above-described example but may have a multilayer structure (upper layer metal and lower layer metal). The material of the upper layer metal is selected such that a highly resistive or insulative interface is formed between the upper layer metal and the first semiconductor layer 21. The material of the lower layer metal is selected such that a low-resistance ohmic contact is formed between the lower layer metal and the second semiconductor layer 22. Herein, as will be described in the following section, it is preferred that a material which has high reflectance for ultraviolet light is in contact with at least the emission layer 23.

When the first semiconductor layer 21 is made of p-GaN, formation of an ohmic contact is difficult in general, and the damage by the etching for device isolation forms the resistance between the p-GaN and the metal plug 24. Therefore, as shown in FIG. 3, the problem of an electrical short circuit between the first semiconductor layer 21 and the second semiconductor layer 22 due to the metal plug 24 is avoided.

<Inclination Angle and Material of Reflector>

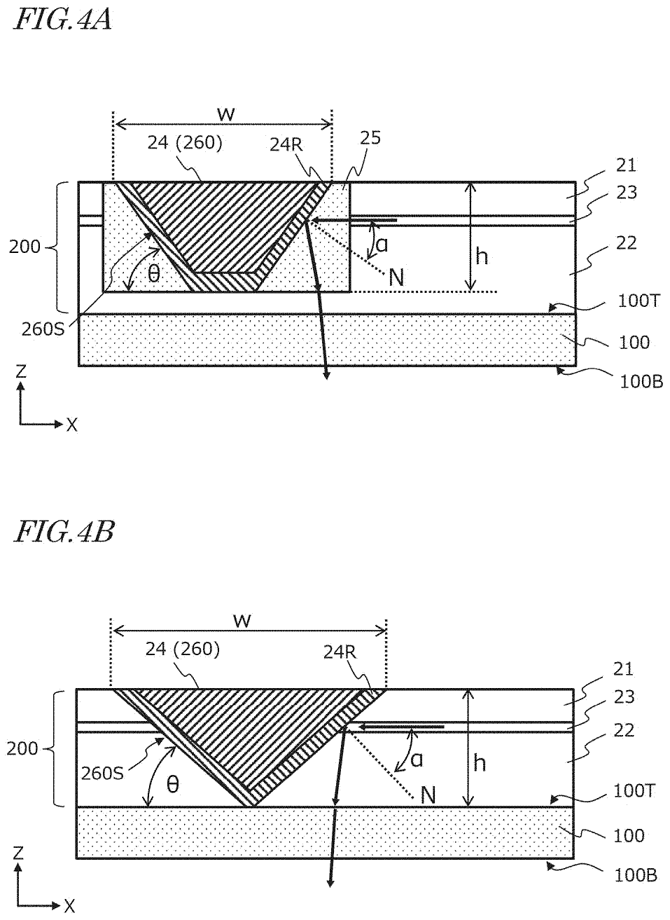

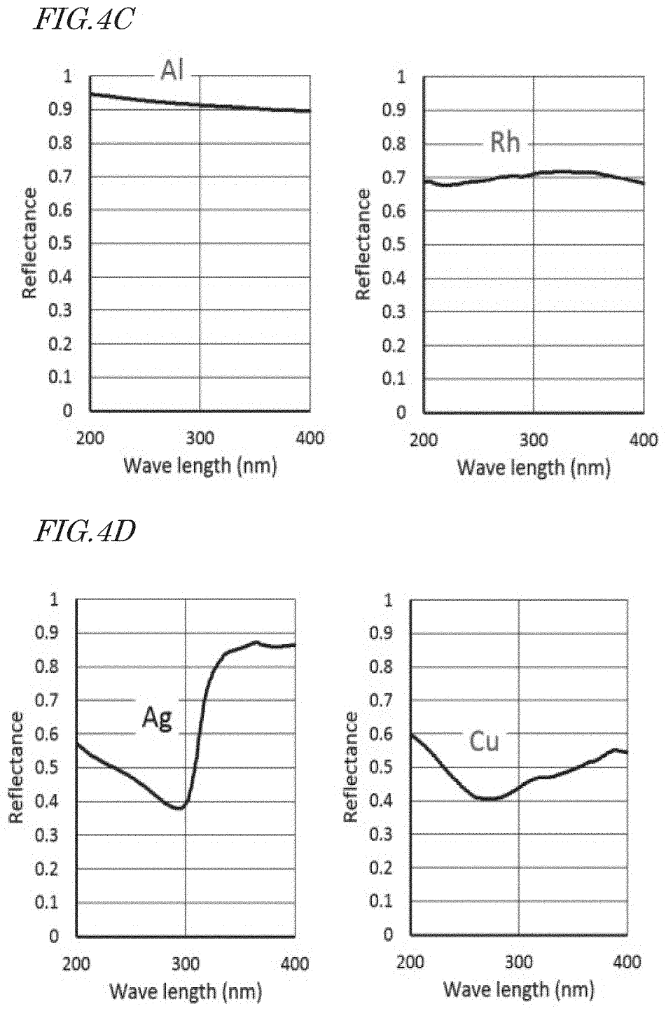

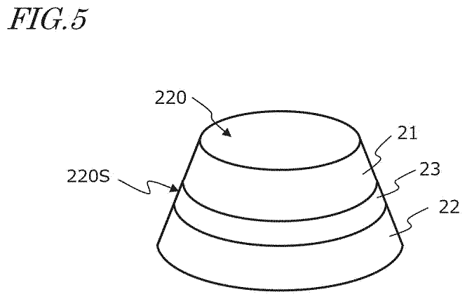

FIG. 4A and FIG. 4B schematically show reflection by the metal plug 24 of ultraviolet light produced at the emission layer 23. In the examples shown in the drawings, part of the metal plug 24 which is to reflect ultraviolet light includes a high-reflectance layer 24R. The high-reflectance layer 24R functions as the reflector 260. The ultraviolet light produced at the emission layer 23 in the μLED is basically isotropically radiated but is likely to be guided horizontally along the emission layer 23 that has a relatively-large bandgap and a high refractive index. Thus, for realizing high reflectance and enabling the ultraviolet light to be incident on the substrate 100 at an appropriate angle, the inclination angle of the reflector 260 with respect to the emission layer 23 is important.

The reflecting surface 260S of the reflector 260 shown in FIG. 4A and FIG. 4B reflects the ultraviolet light received from the emission layer 23 such that the reflected ultraviolet light travels downward (in the negative direction of Z axis).

In the present disclosure, the angle between the reflecting surface 260S of the reflector 260 and the XY plane is defined as “inclination angle θ of reflecting surface”. The angle of the ultraviolet light transmitted through the emission layer 23 with respect to the normal N of the reflecting surface 260S is α. Herein, θ+α=90° holds. The ultraviolet light reflected by the reflecting surface 260S travels in a direction which forms an angle of |2θ−90| degrees with respect to the negative direction of Z axis. The angle represented by |2θ−90| degrees with respect to the negative direction of Z axis is herein referred to as “substrate incidence angle”.

In the example shown in FIG. 4B, the side surface of the semiconductor layers 21, 22, 23 (the side surface 220S of the μLED 220) is inclined at inclination angle θ and forms a forward taper. The present inventor conducted a simulation based on the configuration example shown in FIG. 4B and found that, for realizing extraction of the ultraviolet light, the substrate incidence angle needs to be 25° or smaller, and is preferably 15° or smaller, more preferably 10° or smaller. Therefore, the inclination angle of the reflecting surface 260S of the reflector 260, θ, needs to be in the range of 32.5° to 57.5°. The angle θ is preferably in the range of 37.5° to 52.5°, more preferably in the range of 40° to 50°.

When the angle θ is in the range of 40° to 50°, a high light extraction efficiency of about 90% is realized. However, such a high light extraction efficiency is achieved when the substrate 100 is made of sapphire, but is not achieved when the substrate 100 is made of any other material, for example, GaN. Specifically, when the substrate 100 is a GaN substrate, ultraviolet light at the wavelength of not more than 375 nm cannot be extracted even if the substrate incidence angle is 0°.

As will be described later, a titanium nitride (TiN) layer may be provided on the upper surface 100T of the substrate 100. The TiN layer contributes to crystal growth but affects transmission of the ultraviolet light. According to the research by the present inventor, when the substrate incidence angle is 23° or smaller, extraction of the ultraviolet light is possible. When there is a TiN layer of 5-15 nm in thickness, the substrate incidence angle is preferably 10° or smaller. So long as the substrate incidence angle is 10° or smaller, the light extraction efficiency of not less than 60° can be realized.

The material of the reflecting surface 260S of the metal plug 24 (reflector 260) is preferably Al or Rh, which has high reflectance for ultraviolet light. When the reflecting surface 260S is realized by an Al or Rh layer, the inside of the metal plug 24 (reflector 260) may be made of any other metal, for example, Cu, Ag, Ti, TiN, or the like. It was also found that as the thickness of the Al or Rh layer increases up to about 50 mm, the ultraviolet reflectance has a tendency to increase. A preferred thickness of the Al or Rh layer that functions as the reflector is, for example, not less than 30 nm.

According to simulations by the present inventor, even metals which exhibit relatively high reflectances in the wavelength range of visible light, exclusive of Al and Rh, exhibit significantly-decreased reflectances in the wavelength range of, for example, not less than 200 nm and not more than 300 nm, which is used for sterilization. For example, if in the example of FIG. 4B θ=45° and the thickness of the metal film that forms the reflecting surface 260S of the reflector 260 is 30 nm, the reflectance of Al is generally 90% or higher over a wide wavelength range of 200-380 run as shown in FIG. 4C. The reflectance of Rh is also generally 68% or higher over a wide wavelength range of 200-380 nm. On the other hand, for example, as shown in FIG. 4D, the reflectance of Ag is about 85% for the wavelength of 350 nm but decreases to 37% for the wavelength of 295 nm. The reflectance of Cu is 50% or higher for the wavelength of 380 nm and about 40% for the wavelength of around 260-280 nm. Specifically comparing Cu and Ag, the reflectances in the wavelength range of 200 nm to 280 nm are in the relationship of Cu≈Ag. However, in the wavelength range of 280 run to 305 nm, they are in the relationship of Cu>Ag. When the wavelength exceeds 305 nm, they are in the relationship of Ag>>Cu. Thus, Ag is preferred in the wavelength range of more than 305 nm, and Cu is preferred at the wavelength of around 300 mm. Note that Al always exhibits higher reflectance than Ag and Cu in all of these wavelength ranges. Rh exhibits lower reflectance than Ag at the wavelength of not less than 318 nm but exhibits higher reflectance than Ag and Cu in the other wavelength ranges, particularly in the range of not more than 300 nm.

As clearly seen from the foregoing, when the μLED ultraviolet radiation source of the present disclosure is used for sterilization purposes (wavelength: not less than 200 nm and not more than 300 nm, typically not less than 250 nm and not more than 300 nm), it is desirable that at least the reflecting surface 2601 of the reflector 260 is made of Al or Rh.

For achieving high reflectance in the range of ultraviolet light, it is desirable that the thickness of the Al or Rh layer that forms the reflecting surface 260S is not less than about 30 nm. Even if the thickness of this layer is increased to 50 nm or greater, the increase of the reflectance saturates. Therefore, the thickness of the Al or Rh layer in a portion which functions as the reflector 260 is preferably 30-50 nm. The metal plug 24, exclusive of the superficial region of about 30-50 nm in thickness from the side surface, can be made of a material selected from the other metals from the viewpoint of reducing the electrical resistivity or contact resistance without consideration of the ultraviolet reflectance.

From the viewpoint of improving the ohmic contact property with respect to the semiconductor layer, it is preferred to use TiN in the contact portion of the metal plug 24. However, if there is a TiN layer at the reflecting surface 260S, the reflectance for ultraviolet light will decrease. When there is a metal layer other than the Al layer such as TiN layer at the reflecting surface 260S, it is preferred that the angle θ is 40° or smaller. As the angle θ decreases, the reflectance improves.

The size in X-axis direction or Y-axis direction (width W) of the metal plug 24 (reflector 260) may be greater than the size in Z-axis direction (height h) of the metal plug 24. A typical example of the proportion of the width to the height (W/h) of the metal plug 24 can be not less than 0.5 and not more than 10.

In FIG. 4A and FIG. 4B, the cross section of the metal plug 24 (reflector 260) has the shape of an inverted trapezoid or an inverted triangle, although the cross-sectional shape of the metal plug 24 (reflector 260) is not limited to such examples. The side surface 220S of each μLED 220 does not need to be a flat surface. FIG. 5 is a perspective view showing an example where the side surface 2208 of the μLED 220 is formed by a lateral surface of a truncated cone. The shape of each μLED 220 can be formed by any frustum whose base is polygonal, circular or elliptical.

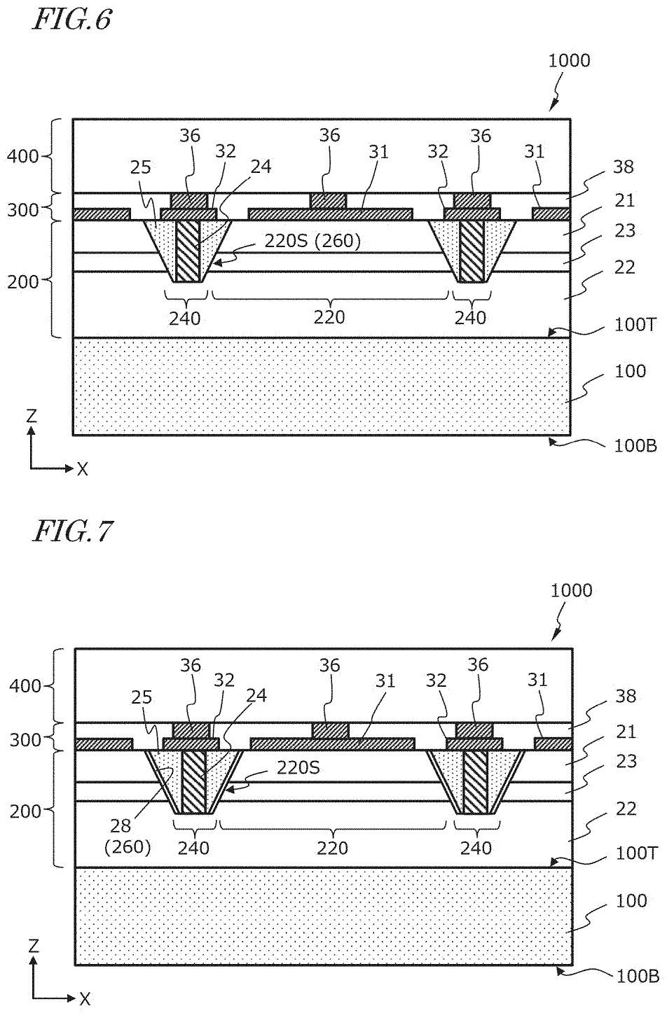

FIG. 6 is a cross-sectional view showing still another configuration example of the μLED UV source 1000. Also in this example, each of the plurality of μLEDs 220 has a forwardly-tapered side surface 220S. However, the metal plug 24 is not in contact with the side surface 220S of each of the μLEDs. In this example, the metal plug 24 is located inside a through hole formed in the embedded insulator 25. In this example, the reflector 260, which is capable of reflecting ultraviolet light radiated from each of the μLEDs 220 such that the reflected ultraviolet light travels toward the crystal growth substrate 100, is the interface between the embedded insulator 25 and the μLED 220 (side surface 220S). Such an interface reflection is Fresnel reflection which is attributed to the difference between the refractive index of the embedded insulator 25 and the refractive index of the μLED 220. The refractive index of a semiconductor which can be a constituent of the μLED 220 is, for example, in the range of not less than 2.1 and not more than 3.0. When the embedded insulator 25 is made of a dielectric which has a lower refractive index than these refractive indices, total reflection of ultraviolet light radiated from the emission layer 23 can be caused by adjusting the inclination angle of the reflecting surface.

The refractive index of the embedded insulator 25 may be higher than the refractive index of the μLED 220.

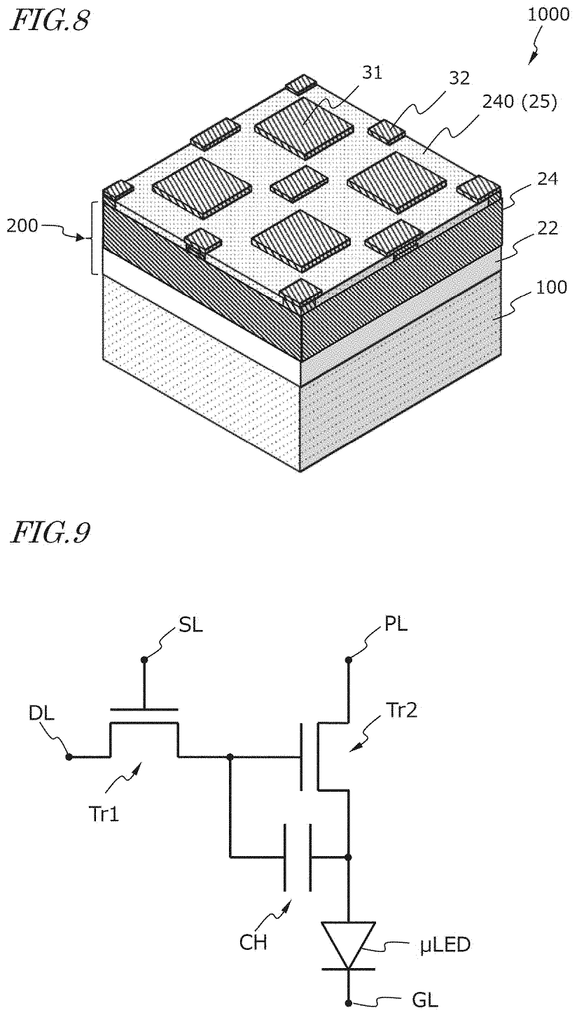

FIG. 7 is a cross-sectional view showing still another configuration example of the μLED UV source 1000. Also in this example, each of the plurality of μLEDs 220 has a forwardly-tapered side surface 220S. However, in this example, the reflector 260 is formed by the reflecting layer 28 which is in contact with the side surface 220S of the μLED 220. This reflecting layer 28 can be a dielectric multilayer film realized by alternately stacking up a plurality of dielectric layers of different refractive indices. Herein, for example, SiO₂ (refractive index n=1.47) and TiO₂ (n=2.7) can be suitably used as the dielectric film. In this case, respective film thicknesses are adjusted, and the films are stacked up over five or more periods, such that the reflectance of the dielectric multilayer film can be 95¹ or higher.

The ultraviolet light reflected by the above-described reflector 260 toward the crystal growth substrate 100 is transmitted through the crystal growth substrate 100 together with ultraviolet light radiated from the μLED 220 directly toward the crystal growth substrate 100, and goes out of the μLED UV source. Such ultraviolet light can be employed in various uses.

<Middle Layer>

The middle layer 300 includes a plurality of first contact electrodes 31 and second contact electrodes 32 (see FIG. 1A). The plurality of first contact electrodes 31 are, respectively, electrically coupled with the first semiconductor layers 21 of the plurality of μLEDs 220. At least one second contact electrode 32 is coupled with the metal plug 24.

FIG. 8 is a perspective view showing an arrangement example of the first contact electrodes 31 and the second contact electrodes 32. In FIG. 9, illustration of the backplane 400 is omitted for showing the arrangement example of the contact electrodes 31, 32. The structure shown in FIG. 8 is merely a part of the μLED UV source 1000. As previously described, an embodiment of the μLED UN source 1000 includes a large number of μLEDs 220.

The second contact electrodes 32 shown in FIG. 8 are electrically coupled with the second semiconductor layer 22 via the metal plugs 24. The shape and size of the second contact electrodes 32 are not limited to the example shown in the drawing. Since the metal plugs 24 can have various shapes as previously described, the flexibility in arrangement of the second contact electrodes 32 is high so long as they are electrically coupled with the second semiconductor layer 22 via the metal plugs 24. Meanwhile, respective ones of the first contact electrodes 31 are independently electrically coupled with the first semiconductor layers 21 of the plurality of μLEDs 220. When viewed in a direction perpendicular to the upper surface 100T of the substrate 100, the shape and size of the first contact electrodes 31 do not need to be identical with the shape and size of the first semiconductor layers 21.

Since the upper surface of the frontplane 200 is planarized as previously described, the distances from the substrate 100 to the first contact electrodes 31 and the second contact electrodes 32, in other words, the “heights” or “levels” of the contact electrodes 31, 32, are mutually equal. This feature facilitates formation of the backplane 400 (described later) with the use of a semiconductor manufacture technique. In the present disclosure, the “semiconductor manufacture technique” includes the process of depositing a thin film of a semiconductor, insulator, or conductor and the process of patterning the thin film by lithography and etching. In this specification, a “planarized surface” means a surface at which the level difference caused by raised or recessed portions at the surface is not more than 300 nm. In a preferred embodiment, this level difference is not more than 100 nm.

Refer again to FIG. 1A. In the example shown in FIG. 1A, the middle layer 300 includes an interlayer insulating layer 38 which has a flat surface. The interlayer insulating layer 38 has a plurality of contact holes for respectively coupling the first and second contact electrodes 31, 32 with the electric circuit of the backplane 400. The contact holes are filled with via electrodes 36.

In an embodiment of the present disclosure, it is preferred to planarize the upper surface of the interlayer insulating layer 38 prior to formation of the backplane 400. In planarizing the insulating layer prior to, or in the middle of, formation of the backplane 400, chemical mechanical polishing (CMP) can be preferably used instead of etch back.

<Backplane>

The backplane 400 includes an electric circuit which is not shown in FIG. 1A. The electric circuit is electrically coupled with the plurality of μLEDs 220 via the plurality of first contact electrodes 31 and at least one second contact electrode 32. In a preferred embodiment, the electric circuit includes a plurality of thin film transistors (TFTs) and other circuit components. As will be described later, each of the TFTs includes a semiconductor layer deposited on the frontplane 200 supported by the substrate 100 and/or on the middle layer 300. Note that some uses do not require the plurality of μLEDs 220 to carry out an active matrix operation. When used for such uses, the electric circuit of the backplane 400 does not need to include TFTs. Note that even when the electric circuit of the backplane 400 does not include TFTs, this electric circuit includes a layer of a metal, semiconductor, and/or insulative material directly grown on the middle layer 300 by physical or chemical vapor deposition (grown layers or deposited layers). These layers are patterned by lithography techniques.

FIG. 9 is a basic equivalent circuit diagram in a case where the μLED UV source 1000 radiates ultraviolet light by the units of μLED. In the example shown in FIG. 9, the electric circuit of the backplane 400 includes a selection TFT element Tr1, a driving TFT element Tr2, and a holding capacitance CH. The μLED shown in FIG. 9 is present in the frontplane 200 rather than the backplane 400.

In the example of FIG. 9, the selection TFT element Tr1 is coupled with an intensity signal line DL and a selection line SL. The intensity signal line DL is an interconnection for carrying signals which define the intensity of ultraviolet radiation. The intensity signal line DL is electrically coupled with the gate of the driving TFT element Tr2 via the selection TFT element Tr1. The selection line SL is an interconnection for carrying signals which control the ON/OFF of the selection TFT element Tr1. The driving TFT element Tr2 controls the state of conduction between a power line PL and the μLED. When the driving TFT element Tr2 is ON, an electric current flows from the power line PL to the ground line 6L via the μLED. This electric current causes the μLED to emit light. If the selection TFT element Tr1 is turned OFF, the ON state of the driving TFT element Tr2 is maintained by the holding capacitance CB.

The backplane 400 that has the above-described configuration can control the radiation intensity of ultraviolet light by the units of μLED. This can widely expand the uses of the ultraviolet radiation source. For example, a resin to be cured with ultraviolet light can be irradiated with ultraviolet light which has an arbitrary intensity distribution in a maskless lithography. Also, the intensity distribution of ultraviolet irradiation can be easily changed according to the input intensity signal.

The electric circuit of the backplane 400 can include the selection TFT element Tr1, the driving TFT element Tr2, the intensity signal line DL, the selection line SL, and other elements, although the configuration of the electric circuit is not limited to such an example. By adjusting the shape, size, and arrangement of respective μLEDs included in the μLED UV source 1000, various intensity distributions of ultraviolet irradiation can be realized. Even if that intensity distribution is fixed for each μLED UV source 1000, it is sufficient for some uses.

<Production Method>

Next, a basic example of the method of producing the μLED UV source 1000 is described.

Firstly, as shown in FIG. 10A, a substrate 100 is provided which has an upper surface (crystal growth surface) 100T. FIG. 10A shows only a part of the substrate 100 extending across a plane which is parallel to the upper surface 100T.

Then, a plurality of semiconductor layers, including a second semiconductor layer 22 of the second conductivity type, an emission layer 23, and a first semiconductor layer 21 of the first conductivity type, are epitaxially grown from the upper surface 100T of the substrate 100. Each of the semiconductor layers is a monocrystalline epitaxially-grown layer of a gallium nitride based compound semiconductor. The epitaxial growth of the gallium nitride based compound semiconductor can be carried out by, for example, MOCVD (Metal Organic Chemical Vapor Deposition). Impurities which define each conductivity type can be introduced for doping from a gaseous phase during the crystal growth.

After a semiconductor multilayer structure 230 which includes the above-described semiconductor layers is formed on the substrate 100, a mask M1 is formed on the first semiconductor layer 21 as shown in FIG. 10B. The mask M1 has an opening which defines the shape and position of the device isolation region 240. In other words, the mask M1 defines the shape and position of the μLEDs 220. Part of the semiconductor multilayer structure 280 which is not covered with the mask H1 is etched from the upper surface, whereby a trench which defines the device isolation region 240 is formed as shown in FIG. 10C. This etching (mesa etching) can be carried out by, for example, inductively coupled plasma (ICP) etching or reactive ion etching (PIE). The depth of the etching is determined such that the second semiconductor layer 22 appears at the bottom of the trench. The depth of the trench formed by etching can be, for example, not less than 0.5 μm and not more than 5 μm. The width of the trench can be, for example, not less than 5 μm and not more than 100 μm. From the viewpoint of improving the in-plane uniformity of the ultraviolet irradiation intensity, it is preferred that the width of the trench is small. The transverse dimension of each of the μLEDs 220 can be not less than 5 μm and not more than 1000 μm, for example, 10-100 μm. For selectively performing ultraviolet irradiation on an arbitrary patterned region, it is preferred to reduce the size of each of the two-dimensionally arrayed μLEDs 220 (for example, it is preferred to reduce the size so as to be within a region of 100 μm×100 μm or smaller or within a stripe region of 100 μm in width). Side surfaces 220S of the μLEDs 220 are exposed by etching. In other words, each of the μLEDs 220 has etched side surfaces 220S. Although in the example of FIG. 10C the side surface 220S is not inclined, the previously-described forwardly-tapered side surface can be formed by adjusting the material of the mask M1 and the etching conditions.

Then, after the device isolation region 240 including the metal plug 24 is formed, first contact electrodes 31 and second contact electrodes 32 are formed as shown in FIG. 8 that has been previously referred to. Then, an interlayer insulating layer 38 (thickness: for example, 500 nm to 1500 nm) of the middle layer 300 is formed and, thereafter, a plurality of contact holes (not shown in FIG. 8) are formed in the interlayer insulating layer 38 for coupling the electric circuit of the backplane 400 with the μLEDs 220 of the frontplane 200. The contact holes are formed so as to reach the contact electrodes 31, 32 which are present in the underlying layer. The contact holes are filled with via electrodes. The upper surface of the interlayer insulating layer 38 can be planarized by CMP.

Then, as shown in FIG. 10D, a backplane 400 is formed on the middle layer 300. A characteristic feature of the present disclosure resides in that various electronic elements and interconnections which are constituents of the backplane 400 are directly formed by a semiconductor manufacture technique on a multilayer stack which includes the frontplane 200 and the middle layer 300, rather than adhering the backplane 400 onto the middle layer 300. As a result, each of a plurality of TFTs included in the backplane 400 includes semiconductor layers deposited on the multilayer stack that includes the frontplane 200 supported by the substrate 100 and the middle layer 300.

As previously described, when the upper surface of the frontplane 200 and the upper surface of the middle layer 300 are planarized, it is easy to produce the backplane 400 which includes the TFTs by a semiconductor manufacture technique. In general, when TFTs are formed by a semiconductor manufacture technique, it is necessary to perform patterning of deposited semiconductor layers, insulating layers, and metal layers. The patterning is realized by a lithography process which involves exposure to light. If there is a large step in the underlayer of the deposited semiconductor layers, insulating layers, and metal layers, light will not be correctly focused in the exposure so that micropatterning with high precision cannot be realized. In an embodiment of the present disclosure, the entirety of the frontplane 200 including the device isolation region 240 is planarized and, accordingly, the middle layer 300 is also planarized, so that it is easy to form the backplane 400 by a semiconductor manufacture technique.

In the configuration example which has previously been described with reference to FIG. 10A to FIG. 10D, the shape of the μLEDs 220 is generally rectangular parallelepipedic, although the shape of the μLEDs 220 may be the shape of a cylindrical pillar, a polygonal pillar such as hexagonal pillar, or an elliptical pillar. Also, the μLEDs 220 may have an inclined side surface as shown in FIG. 4B.

### Embodiment 1

Hereinafter, a basic embodiment of a μLED UV source of the present disclosure is described in more detail.

Refer to FIG. 11. The PLED UV source 1000 of the present embodiment is an ultraviolet radiation source which has the same configuration as the previously-described basic configuration example. The μLED UV source 1000 includes a substrate 100 which is made of sapphire, a frontplane 200 provided on the substrate 100, a middle layer 300 provided on the frontplane 200, and a backplane 400 provided on the middle layer 300.

Next, an example of the configuration and production method of the μLED UV source 1000 of the present embodiment is described with reference to FIG. 12A through FIG. 15.

First, refer to FIG. 12. In the present embodiment, a substrate 100 is placed in a reactor of a MOCVD apparatus, and various gases are supplied into the reactor for carrying out epitaxial growth of a gallium nitride (GaN) based compound semiconductor. In the present embodiment, the substrate 100 is a sapphire substrate whose thickness is, for example, about 50-600 μm. The upper surface 100T of the substrate 100 is typically a C-plane (0001), although the substrate 100 may have a nonpolar or semipolar plane, such as m-plane, a-plane, and r-plane, at the upper surface. The upper surface 100T may be inclined by about several degrees from these crystal planes. The substrate 100 typically has the shape of a circular plate. The diameter of the substrate 100 can be, for example, from 1 inch to 8 inches. The shape and size of the substrate 100 are not limited to this example. The substrate 100 may have a rectangular shape. The production process may be carried on using a substrate 100 in the shape of a circular plate, and the substrate 100 may be processed into a rectangular shape by cutting away peripheral parts of the substrate 100 in the final steps. Alternatively, the production process may be carried on using a relatively-large substrate 100, and the single substrate 100 may be divided into a plurality of μLED UV sources in the final steps (singulation).

Firstly, trimethyl gallium (TMG) or triethyl gallium (TEG), hydrogen (H₂) as the carrier gas, nitrogen (N₂), ammonia (NH₃), and silane (SiH₄) are supplied into the reactor of the MOCVD apparatus. The substrate 100 is heated to about 1100° C., and an n-GaN layer 22n (thickness: for example, 2 μm) is grown. Silane is a material gas for supplying Si as the n-type dopant. The doping concentration of the n-type impurity can be, for example, 5×10¹⁷ cm⁻³.

Then, supply of SiH₄ is stopped, the substrate 100 is cooled to a temperature lower than 800° C., and an emission layer 23 is formed. Specifically, firstly, an AlₓIn_{y}Ga_{z}N (0≤x<1, 0<y<1, 0<z<1) barrier layer is grown. Further, supply of trimethyl indium (TMI) is started, and an Al_{x′}In_{y′}Ga_{z′}N (0≤x′<1, 0<y′<1, 0<z′<1) well layer is grown. The barrier layer and the well layer are alternately grown over two or more periods, whereby an emission layer 23 (thickness: for example, 100 nm), including a multi-quantum well which functions as the light-emitting part, can be formed. As the number of well layers is larger, the carrier density inside the well layers can be prevented from being excessively large in driving with a large electric current. A single emission layer 23 may include a single well layer interposed between two barrier layers. A well layer may be directly formed on the n-GaN layer 22n, and a barrier layer may be formed on the well layer.

After the emission layer 23 is formed, supply of TMI is once stopped. Thereafter, nitrogen is added to the carrier gas (hydrogen), supply of ammonia is resumed, the growth temperature is increased to a temperature in the range of 850° C. to 1000° C., and trimethyl aluminum (TMA) and biscyclopentadienyl magnesium (Cp₂Mg) as the material for Mg as the p-type dopant are supplied, whereby an overflow suppression layer may be grown. Then, supply of TMA is stopped, and a p-GaN layer 21p (thickness: for example, 0.5 μm) is grown. The doping concentration of the p-type impurity can be, for example, 5×10¹⁷ cm⁻³.

An n-AlGaN layer may be provided between the n-GaN layer 22n and the emission layer 23. The n-GaN layer 22n may be replaced by an n-AlGaN layer. Alternatively, a p-AlGaN layer may be provided between the emission layer 23 and the p-GaN layer 21p.

Then, as shown in FIG. 125, photolithography and etching are performed on the substrate 100 pulled out of the reactor of the MOCVD apparatus, whereby predetermined regions of the p-GaN layer 21p and the emission layer 23 (portions in which the device isolation region 240 is to be formed; Depth: for example, 1.5 μm) are removed such that the n-GaN layer 22n is partially exposed. Etching of the gallium nitride based semiconductor can be carried out using a plasma of a chloric gas as will be described later.

As shown in FIG. 12C, the spaces that define the device isolation region 240 are filled with the embedded insulator 25. The material and formation method of the embedded insulator 25 are arbitrary so long as they are selected from materials which are capable of transmitting ultraviolet light and their formation methods. In the example shown in the drawing, the upper surface of the embedded insulator 25 is planarized and located at the same level as the upper surface of the p-GaN layer 21p.

As shown in FIG. 12D, through holes 26 are formed in part of the embedded insulator 25 so as to reach the n-GaN layer 22n. The through holes 26 define the position and shape of the metal plugs 24. In this example, the side surfaces of the through holes 26 are inclined such that the metal plugs 24 function as reflectors. The through holes 26 contain the metal plugs 24 which have such a shape as shown in FIG. 1B.

As shown in FIG. 12E, metal plugs 24 are formed so as to fill the through holes 26, and the upper surface of the frontplane 200 is planarized. Thereafter, first contact electrodes 31 and second contact electrodes 32 are formed. The planarization can be carried out through various processes such as, for example, etch back, selective growth, or lift off.

The metal plugs 24 can be made of metal, for example, titanium (Ti) and/or aluminum (Al), such that an ohmic contact with the n-GaN layer 22n can be established. The metal plugs 24 preferably include a metal layer which contains Ti in a portion in contact with the n-GaN layer 22n (e.g., TiN layer). The presence of the TiN layer contributes to realization of a low-resistance n-type ohmic contact. The TIN layer can be formed by forming a Ti layer so as to be in contact with the n-GaN layer 22n and thereafter performing a heat treatment at, for example, about 600° C. for 30 seconds. In a portion which is to reflect ultraviolet light, Al or Rh is desirably present as previously described.

The first and second contact electrodes 31, 32 can be formed by deposition and patterning of a metal layer. Between the first contact electrodes 31 and the p-GaN layer 21p of the μLEDs 220, a metal-semiconductor interface is formed. To realize a p-type ohmic contact, the material of the first contact electrodes 31 can be selected from metals which have large work functions, for example, platinum (Pt) and/or palladium (Pd). After a layer of Pt or Pd (thickness: about 50 nm) is formed, a heat treatment can be performed at a temperature of, for example, not less than 350° C. and not more than 400° C. for about 30 seconds. So long as a layer of Pt or Pd is present in a portion which is in direct contact with the p-GaN layer 21p, a layer of a different metal, for example, a Ti layer (thickness: about 50 nm) and/or an Au layer (thickness: about 200 nm), may be formed on that layer.

In the upper part of the p-GaN layer 21p, a region doped with the p-type impurity at a relatively-high concentration may be formed. The second contact electrodes 32 are electrically coupled with the metal plugs 24 rather than the semiconductor. Therefore, the material of the second contact electrodes 32 can be selected from a wide range. The first contact electrodes 31 and the second contact electrodes 32 may be formed by patterning a single continuous metal layer. This patterning also includes lift off. If the first contact electrodes 31 and the second contact electrodes 32 have equal thicknesses, connection with the electric circuit in the backplane 400, such as TFT 40 which will be described later, will be easy.

After the first and second contact electrodes 31, 32 are formed, these electrodes are covered with an interlayer insulating layer 38 (thickness: for example, 1000 nm to 1500 nm). In a preferred example, the upper surface of the interlayer insulating layer 38 can be planarized by CMP or the like. The thickness of the interlayer insulating layer 38 that has the planarized upper surface means “average thickness”.

As shown in FIG. 12F, contact holes 39 are formed in the interlayer insulating layer 36. The contact holes 39 are used for electrically coupling the electric circuit of the backplane 400 with the μLEDs 220 of the frontplane 200.

Hereinafter, a configuration example and formation method of TFTs included in the electric circuit of the backplane 400 are described with again reference to FIG. 11.

In the example shown in FIG. 11, the TFT 40 includes a drain electrode 41 and a source electrode 42 which are provided on the interlayer insulating layer 38, a semiconductor thin film 43 which is in contact with at least part of the upper surface of each of the drain electrode 41 and the source electrode 42, a gate insulating film 44 provided on the semiconductor thin film 43, and a gate electrode 45 provided on the gate insulating film 44. In the example shown in the drawing, the drain electrode 41 and the source electrode 42 are coupled with the first contact electrode 31 and the second contact electrode 32, respectively, via the via electrodes 36. These constituents of the TFT 40 are formed by a known semiconductor manufacture technique.

The semiconductor thin film 43 can be made of polycrystalline silicon, amorphous silicon, oxide semiconductor, and/or gallium nitride based semiconductor. The polycrystalline silicon can be formed by depositing amorphous silicon on the interlayer insulating layer 38 of the middle layer 300 by, for example, a thin film deposition technique and thereafter crystallizing the amorphous silicon with a laser beam. The thus-formed polycrystalline silicon is referred to as LTPS (Low-Temperature Poly Silicon). The polycrystalline silicon is patterned into a desired shape by lithography and etching.

In FIG. 11, the TFT 40 is covered with an insulating layer 46 (thickness: for example, 500 nm to 3000 nm). The insulating layer 46 has an unshown hole which enables coupling of, for example, the gate electrode 45 of the TFT 40 with an external driver integrated circuit device or the like. Preferably, the upper surface of the insulating layer 46 is also planarized. The electric circuit of the backplane 400 can include circuit components such as unshown TFTs, capacitors, and diodes. Thus, the insulating layer 46 may have a configuration where a plurality of insulating layers are stacked up. In this case, each of the insulating layers can include a via electrode for coupling circuit components when necessary. On each of the insulating layers, interconnections can be formed when necessary.

In the present embodiment, the backplane 400 can have the same configuration as a known backplane for use in display devices (e.g., TFT substrate). Note that, however, the backplane 400 of the present disclosure is characterized in that it is formed on the μLEDs 220 in the underlying layer by a semiconductor manufacture technique. Therefore, for example, the drain electrode 41 and the source electrode 42 of the TFT 40 can be formed by patterning a metal layer which is deposited so as to cover the frontplane 200. Such patterning enables high-precision aligning which is based on lithography techniques. Particularly in the present embodiment, the frontplane 200 and/or the middle layer 300 are planarized and, therefore, it is possible to increase the resolution of the lithography. As a result, it is possible to produce a device which includes a large number of μLEDs 220 aligned at a microscopic pitch of for example not more than 20 μm, in an extreme example not more than 5 μm, at a high yield and at a low cost.

The configuration of the TFT 40 shown in FIG. 11 is exemplary. For the sake of clear description, in the example described herein, the drain electrode 41 of the TFT 40 is electrically coupled with the first contact electrode 31, although the drain electrode 41 of the TFT 40 may be coupled with any other circuit component or interconnection included in the backplane 400. The source electrode 42 of the TFT 40 does not need to be electrically coupled with the second contact electrode 32. The second contact electrode 32 can be coupled with an interconnection which commonly gives a predetermined potential to the n-GaN layers 22n of the μLEDs 220 (e.g., ground interconnection).

In the present embodiment, the electric circuit of the backplane 400 includes a plurality of metal layers which are respectively coupled with the first contact electrode 31 and the second contact electrode 32 (metal layers which function as the drain electrode 41 and the source electrode 42). In the present embodiment, the plurality of first contact electrodes 31 respectively cover the p-GaN layers 21p of the plurality of μLEDs 220 and function as a light-blocking layer or a light-reflecting layer. Each of the first contact electrodes 31 does not need to cover the upper surface of the μLED 220, i.e., the entirety of the upper surface of the p-GaN layer 21p. The shape, size, and position of the first contact electrodes 31 are determined such that sufficiently-low contact resistance is realized while the first contact electrodes 31 sufficiently suppress arrival of ultraviolet light radiated from the emission layer 23 at the channel region of the TFT 40. Prevention of arrival of ultraviolet light radiated from the emission layer 23 at the channel region of the TFT 40 can also be realized by arranging the other metal layers at appropriate positions.

According to an embodiment of the present disclosure, the middle layer 300 that has a planarized upper surface is formed on the frontplane 200 that has a flat upper surface which is realized by filling the device isolation region 240 with the metal plugs 24 and the embedded insulator 25. These structures (underlying structures) function as a base on which circuit components such as TFTs are to be formed. In depositing semiconductors for TFT or in performing a heat treatment after the deposition, the above-described underlying structures are treated at, for example, 350° C. or higher. Thus, the embedded insulator 25 in the device isolation region 240 and the interlayer insulating layer 38 included in the middle layer 300 are preferably made of a material which will not be degraded even by a heat treatment at 350° C. or higher. For example, polyimide and SOG (Spin-on Glass) can be suitably used.

The configuration of TFTs included in the electric circuit in the backplane 400 is not limited to the above-described examples.

FIG. 13 is a cross-sectional view schematically showing another example of the TFT. FIG. 14 is a cross-sectional view schematically showing still another example of the TFT.

In the example of FIG. 13, the TFT 40 includes a drain electrode 41, a source electrode 42, and a gate electrode 45 which are provided on the interlayer insulating layer 36, a gate insulating film 44 which is provided on the gate electrode 45, and a semiconductor thin film 43 which is provided on the gate insulating Film 44 so as to be in contact with at least part of the upper surface of each of the drain electrode 41 and the source electrode 42. In the example shown in the drawing, the drain electrode 41 and the source electrode 42 are coupled with the first contact electrode 31 and the second contact electrode 32, respectively, via the via electrodes 36.

In the example of FIG. 14, the TFT 40 includes a semiconductor thin film 43 provided on the interlayer insulating layer 38, a drain electrode 41, and a source electrode 42 which are provided on the interlayer insulating layer 38 so as to be in contact with part of the semiconductor thin film 43, a gate insulating film 44 provided on the semiconductor thin film 43, and a gate electrode 45 provided on the gate insulating film 44. In the example shown in the drawing, the drain electrode 41 and the source electrode 42 are coupled with the first contact electrode 31 and the second contact electrode 32, respectively, via the via electrodes 36.

The configuration of the TFT 40 is not limited to the above-described examples. In an embodiment of the present disclosure, in the initial phase of the process of forming the TFT 40, a plurality of metal layers are formed so as to be in contact with the first and second contact electrodes 31, 32 of the frontplane 200 via the contact holes 39 of the interlayer insulating layer 38 in the middle layer 300. These metal layers can be the drain electrode 41 or the source electrode 42 of the TFT 40 but are not limited to such examples.

In the present embodiment, the drain electrode 41 and the source electrode 42 are formed by depositing a metal layer on the interlayer insulating layer 39 in the planarized middle layer 300 and thereafter patterning the metal layer by photolithography and etching. Therefore, misalignment which can cause decrease in yield will not occur between the frontplane 200 (the middle layer 300) and the backplane 400.

<TiN Buffer Layer>

FIG. 15 is a cross-sectional view schematically showing part of a μLED UV source which includes a titanium nitride (TIN) layer 50 located between the substrate 100 and the n-GaN layer 22n of each of the μLEDs 220. The thickness of the TiN layer 50 can be, for example, not more than 5 nm and not less than 20 nm. The TiN layer 50 can be suitably used in combination with a substrate 100 which is made of sapphire.

The TiN layer 50 is electrically conductive. In an embodiment of the present disclosure, a large number of μLEDs 220 are arrayed over a wide area, and at least one metal plug 24 couples the n-GaN layer 22n of the μLEDs 220 with the electric circuit of the backplane 400. Thus, if an electrical resistance component (sheet resistance) relative to the electric current flowing from the n-GaN layer 22n to the metal plug 24 is excessively high, an increase in power consumption will be caused. The TiN layer 50 functions as a buffer layer which relaxes the lattice mismatch in crystal growth and contributes to reduction in density of crystallographic defects, and also contributes to reduction in the above-described electrical resistance component in the operation of the device. The thickness of the TiN layer 50 is preferably not less than 10 nm, more preferably not less than 12 nm, from the viewpoint of reducing the electrical resistance component such that it can function as the substrate-side electrode. Meanwhile, from the viewpoint of transmitting ultraviolet light radiated from the μLEDs 220, the thickness of the TiN layer 50 is preferably, for example, not more than 20 nm, more preferably 5-15 nm.

In the example shown in FIG. 15, a single continuous n-GaN layer 22n (second semiconductor layer) is shared among the plurality of μLEDs 220. However, the n-GaN layer 22n may be isolated for each of the μLEDs 220. In that case, the bottom of a trench which defines the device isolation region 240 reaches the upper surface of the TiN layer 50, and the metal plugs 24 are in contact with the TiN layer 50. Since the single continuous TiN layer 50 is electrically coupled with the n-Gat layer 22n in all of the μLEDs 220, electrical conduction between the metal plug 24 and the n-GaN layer 22n of each of the μLEDs 220 is secured. In this example, the TiN layer 50 functions as the n-side common electrode of the plurality of μLEDs 220. In an embodiment of the present disclosure, the electrodes on the second conductivity side in the plurality of μLEDs 220 are realized in a common form by a semiconductor layer or a TiN layer. Thus, a problem of conduction failure in some of the μLEDs 220 due to interconnection breakage is avoided.

### Embodiment 2

The above-described embodiment has a configuration where a plurality of μLEDs 220 are arrayed on a single continuous substrate 100, although the μLED ultraviolet radiation source of the present disclosure is not limited to such an example.

Hereinafter, another embodiment of the μLED ultraviolet radiation source is described where, for example, the structure shown in FIG. 1A and FIG. 18 is divided into a plurality of light-emitting device units which are supported by a flexible film (flexible substrate).

Firstly, a configuration example of the μLED ultraviolet radiation source in the present embodiment is described with reference to FIG. 16. The μLED ultraviolet radiation source 2000 of the present embodiment basically has the same configuration as the previously-described μLED ultraviolet radiation source 1000. The difference is that, in the μLED ultraviolet radiation source 2000, the structure divided into the plurality of light-emitting device units 10 is supported by a flexible film 520. More specifically, the crystal growth substrate 100, the frontplane 200, the middle layer 300, and the backplane 400 are divided into the plurality of light-emitting device units 10, and each of the plurality of light-emitting device units 10 includes at least one of the plurality of μLEDs 220. Ultraviolet light radiated from the plurality of μLEDs 220 travels through the crystal growth substrate 100 before going out of the micro-LED ultraviolet radiation source 2000. In the previously-described μLED ultraviolet radiation source 1000 of the Embodiment 1, inclusion of a reflector is essential, although the μLED ultraviolet radiation source 2000 of Embodiment 2 does not necessarily need to include a reflector. However, if there is a reflector around the μLEDs 220, not only the effects of improving the extraction efficiency of the ultraviolet light and reducing the optical loss but also the effect of controlling the directivity of ultraviolet radiation by the units of μLED 220 are achieved. In the present embodiment, respective ones of the μLEDs 220 can be oriented in different directions by the flexible film and, therefore, improving the directivity of ultraviolet light radiation from each of the μLEDs by the reflector enables improvement in the degree of freedom and controllability of the radiation pattern produced by the flexible μLED ultraviolet radiation source 2000. Note that, desirably, all of the μLEDs 220 included in each of the divided light-emitting device units 10 is entirely surrounded by the reflector, although this feature is not indispensable.

In the example of FIG. 16, the μLED ultraviolet radiation source 2000 includes a member 600 which has a curved surface or a corner portion. The flexible film 520 is attached to this member 600. In the example of FIG. 16, this member 600 includes a long axis portion which has an inner surface and an outer surface. Specifically, the member 600 has a cylindrical shape elongated in a direction perpendicular to the sheet of the drawing. The flexible film 520 with a plurality of singulated μLEDs 220 mounted thereon is attached to the inner surface of the thus-configured long axis portion. Each of the plurality of light-emitting device units 10 may include a plurality of μLEDs 220 arrayed in a predetermined direction.

In the example of FIG. 16, a material to be subjected to ultraviolet light irradiation, for example, a fluid such as water containing a subject for sterilization, flows through a pipe 620 located at the center. This pipe 620 is made of a material which is capable of excellently transmitting ultraviolet light, for example, quartz. The plurality of light-emitting device units 10, which are arrayed so as to surround the pipe 620, each include a single μLED 220 or a plurality of μLEDs 220 capable of emitting ultraviolet light. Preferably, at least the inner wall surface of the member 600 surrounding the light-emitting device units 10 is made of a material or film capable of reflecting ultraviolet light. Thanks to such features, ultraviolet light radiated from a large number of μLEDs 220 efficiently concentrates inside the pipe 620 and, therefore, an irradiation intensity which is required for processing such as sterilization can be achieved in a short time. Note that, if there is a film of a photocatalytic material deposited on the inner wall of the pipe 620, adhesion of a smear can be prevented. A typical example of such a film is a TiO₂ film. Preferably, the film has such a thickness that does not interrupt transmission of ultraviolet light (e.g., 5-20 nm).

It is not necessary for all the light-emitting device units 10 to concurrently radiate ultraviolet light. When all the light-emitting device units 10 concurrently emit ultraviolet light, uniform irradiation is possible due to the dense array of the μLEDs 220. The irradiation intensity and irradiation duration of the ultraviolet light can also be controlled by the units of light-emitting device unit or by the units of μLED. When such an operation is unnecessary, it is only necessary to provide in the backplane 400 a simple electric circuit for coupling respective units of light-emitting device units or respective units of μLEDs with a common power supply line. However, for realizing an arbitrary irradiation pattern, it is only necessary to provide in the backplane 400 an electric circuit which includes TFTs for active matrix driving, for example.

The form of the LED ultraviolet radiation source 2000 is not limited to an example which has a configuration such as shown in FIG. 16 where ultraviolet light is radiated in a closed space. The flexible film 520 on which the plurality of light-emitting device units 10 are arrayed can be adhered to the surface of an object which has a complicated external shape such that ultraviolet light can be radiated outward. Particularly when the size of each of the light-emitting device units 10 is sufficiently reduced and a reflector is provided, the effect of freely controlling the directivity of ultraviolet light radiation is achieved. Even if the same effect is attempted using a conventional pickup-and-place method, it is practically impossible to mount a large number of μLEDs onto an uneven surface while adjusting the orientation of the μLEDs.

Next, an example of the method for producing the μLED ultraviolet radiation source 2000 is described.

Firstly, the same structure as the μLED ultraviolet radiation source 1000 shown in FIG. 1A and FIG. 1B is produced by the previously-described method. Next, the step of dividing the crystal growth substrate 100 and the multilayer stack on the crystal growth substrate 100 into a plurality of light-emitting device units 10 is performed. Specifically, for example, as shown in FIG. 17A, after a backplane 400 is fixed onto an expandable film 510, cutting is performed with a laser beam or dicing blade at the boundaries of the plurality of light-emitting device units 10. Thereby, cut grooves are formed between adjoining light-emitting device units 10.

Thereafter, the expandable film 510 is expanded, whereby the distance between the centers of the plurality of light-emitting device units 10 is increased as shown in FIG. 173. The distance between the centers before the expansion can be increased, for example, 1.2-2.5 times or more (about 5 times) by the expansion. After the expandable film 510 is expanded, the plurality of light-emitting device units 10 are concurrently or sequentially moved (transferred) to the flexible film 520 as shown in FIG. 175. After the transfer, the expandable film 510 can be removed.

After the flexible film 520 with the plurality of light-emitting device units 10 placed thereon with predetermined intervals is produced in this way, this flexible film 520 is flexibly deformable according to the shape of the surface of an object to which the flexible film 520 is to be fixed. One of the surfaces of the flexible film 520 which faces the backplane 400 is provided with an electrode pad and an interconnection for electrically coupling with the backplane 400. The interconnection may have a material and configuration such that the interconnection can be expanded together with the flexible film 520. An example of such a material is a resin in which electrically-conductive particles are dispersed or an electrically-conductive polymer which itself has electrical conductivity. An example of such a configuration is a meandering or bent interconnection pattern. The interconnection has such a shape that, even when the flexible film 520 is expanded, no breakage occurs in the interconnection.

Then, the entirety of the flexible film 520 and the plurality of light-emitting device units 10 is rolled into a cylindrical shape and, thereafter, inserted into the inside of the cylindrical member 600 shown in FIG. 16 and secured to the inner wall of the member 600. The pipe 620 that is capable of transmitting ultraviolet light is inserted into the hollow part, whereby the configuration shown in FIG. 16 is realized.

In expanding the expandable film 510 from the state of FIG. 17A to the state of FIG. 17B, for example, an expander 800 shown in FIG. 19A can be used. The expander 800 holds the circumferential part of the circular expandable film 510, and the upper surface of a cylindrical movable stage (not shown) is in contact with the rear surface of the expandable film 510. The expander 800 pushes the movable stage to the front side of the drawing with the expandable film 510 being heated at the upper surface of the movable stage while the circumferential part of the expandable film 510 is kept at a predetermined position. As a result, the expandable film 510 can be enlarged radially outward from the center. FIG. 198 shows a state where the expander 800 has moved the movable stage to the front side of the drawing such that the expandable film 510 has been enlarged radially outward from the center. According to the enlargement/expansion of the expandable film 510, the plurality of light-emitting device units 10 supported on the expandable film 510 are respectively positionally shifted such that the gap between the light-emitting device units 10 is enlarged. For example, after in this state the flexible film 520 shown in FIG. 178 is fixed to the expandable film 510, the expandable film 510 can be displaced from the expander 800.

In the example of FIG. 19A and FIG. 19B, the light-emitting device units 10 are cut and separated for singulation such that each of the light-emitting device units 10 has, for example, a smaller size than 1000 μm×1000 m (e.g., 100 μm×100 m), although the embodiments of the present disclosure are not limited to such an example. Each of the light-emitting device units 10 may have a stripe shape elongated in a predetermined direction. For example, when the flexible film 520 is deformed so as to fit the cylinder surface as shown in FIG. 16, the elongation in the long axis direction of the light-emitting device units 10 will not obstruct the deformation.

In the above-described example, the expandable film 510 does not function as a constituent of the final form of the μLED ultraviolet radiation source 2000, although the embodiments of the present disclosure are not limited to such an example. For example, as shown in FIG. 18A, the distance between the centers of the plurality of light-emitting device units 10 may be increased while the backplane 400 of the plurality of divided light-emitting device units 10 is kept fixed to the expandable film 510 such that the structure changes into the state shown in FIG. 185. When the expandable film 510 functions as a flexible film in the final form of the μLED ultraviolet radiation source 2000, an adhesive layer provided in the expandable film 510 is preferably made of an adhesive agent whose adhesion power is not decreased by ultraviolet light irradiation.

After the expansion, an interconnection layer or a function layer such as printed circuit board may be adhered to the rear surface of the flexible film 520 of FIG. 17B or the rear surface of the expandable film 510 of FIG. 18B.

In the example shown in FIG. 17A, the cutting for the dividing is performed from the backplane 400 side, whereas in the example shown in FIG. 18A the cutting is performed from the substrate 100 side. The effects of the cutting on the expandable film 510 or the flexible film 520 can be avoided by adhering another film, for example, a dicing film, to the substrate 100 or the backplane 400 before the cutting and, after the cutting, transferring the resultant structures from the dicing film to the expandable film 510.

The mode of increasing the distance between the centers of the light-emitting device units 10 using the expandable film 510 can have many variations. Also, the shape and configuration of the light-emitting device units 10 can have many variations. Each of the light-emitting device units 10 can include a single μLED 220 or a plurality of μLEDs 220.

The μLED ultraviolet radiation source 2000 shown in FIG. 16 includes the flexible film 520 that is secured to the inner wall surface of the cylindrical member 600 although, when used, the flexible film 520 may be fixed to the outer wall surface of the cylindrical member 600 or may be fixed to an arbitrary member which has various other shapes.

### INDUSTRIAL APPLICABILITY

An embodiment of the present invention provides a novel micro-LED ultraviolet radiation source. The micro-LED ultraviolet radiation source can be used in various uses which require irradiation with ultraviolet light, including curing of a resin with ultraviolet light, exposure of a resist to light, lift-off of a resin film, and sterilization. Particularly, it is useful in a device which requires selectively irradiating a predetermined region with ultraviolet light.

### REFERENCE SIGNS LIST

21 . . . First semiconductor layer, 22 . . . Second semiconductor layer, 23 . . . Emission layer, 24 . . . Metal plug, 25 . . . Embedded insulator, 31 . . . First contact electrode, 32 . . . Second contact electrode, 36 . . . via electrode, 38 . . . Interlayer insulating layer, 100 . . . Crystal growth substrate, 200 . . . Frontplane, 220 . . . μLED, 240 . . . Device isolation region, 300 . . . Middle layer, 400 . . . Backplane, 1000 . . . μLED UV source

1. A micro-LED ultraviolet radiation source comprising:
a crystal growth substrate;
a frontplane on the crystal growth substrate, the frontplane including a plurality of micro-LEDs, each of which includes a first semiconductor layer of a first conductivity type and a second semiconductor layer of a second conductivity type and is capable of radiating ultraviolet light, and a device isolation region located between the plurality of micro-LEDs, the device isolation region including at least one metal plug electrically coupled with the second semiconductor layer;
a middle layer supported by the frontplane, the middle layer including a plurality of first contact electrodes respectively electrically coupled with the first semiconductor layer of the plurality of micro-LEDs and at least one second contact electrode coupled with the metal plug; and
a backplane supported by the middle layer, the backplane including an electric circuit electrically coupled with the plurality of micro-LEDs via the plurality of first contact electrodes and the at least one second contact electrode,
wherein the crystal growth substrate, the frontplane, the middle layer, and the backplane are divided into a plurality of light-emitting device units,
each of the plurality of light-emitting device units includes at least one of the plurality of micro-LEDs, and the ultraviolet light radiated from the plurality of micro-LEDs travels through the crystal growth substrate before going out of the micro-LED ultraviolet radiation source, and
the plurality of light-emitting device units are supported by a flexible film.

2. The micro-LED ultraviolet radiation source of claim 1, wherein the backplane includes a layer of a metal, semiconductor, and/or insulative material deposited on the middle layer.

3. The micro-LED ultraviolet radiation source of claim 1, wherein the device isolation region includes a reflector capable of reflecting ultraviolet light radiated from each of the plurality of micro-LEDs such that the reflected ultraviolet light travels toward the crystal growth substrate.

4. The micro-LED ultraviolet radiation source of claim 3, wherein at least a reflecting surface of the reflector is made of aluminum (Al) or rhodium (Rh).

5. The micro-LED ultraviolet radiation source of claim 4, wherein a wavelength of the ultraviolet light is not less than 200 nm and not more than 380 nm.

6. The micro-LED ultraviolet radiation source of claim 3, wherein at least part of the at least one metal plug functions as the reflector.

7. The micro-LED ultraviolet radiation source of claim 6, wherein
each of the plurality of micro-LEDs has a forwardly-tapered side surface, and
the at least one metal plug is in contact with the side surface of each of the plurality of micro-LEDs.

8. The micro-LED ultraviolet radiation source of claim 1, wherein the crystal growth substrate is a sapphire substrate.

9. The micro-LED ultraviolet radiation source of claim 1, further comprising a member having a curved surface or a corner portion, wherein the flexible film is attached to the curved surface or the corner portion.

10. The micro-LED ultraviolet radiation source of claim 9, wherein
the member includes a long axis portion having an inner surface and an outer surface, the long axis portion being elongated in a predetermined direction, and
the flexible film is attached to the inner surface and/or the outer surface of the long axis portion.

11. The micro-LED ultraviolet radiation source of claim 10, wherein each of the plurality of light-emitting device units includes the plurality of micro-LEDs arrayed in the predetermined direction.

12. The micro-LED ultraviolet radiation source of claim 1, wherein the electric circuit includes a thin film transistor.

13. The micro-LED ultraviolet radiation source of claim 1, wherein in each of the plurality of light-emitting device units, the device isolation region of the frontplane includes an insulator covering a side surface of the plurality of micro-LEDs, the insulator having at least one through hole for the metal plug.

14. The micro-LED ultraviolet radiation source of claim 1, wherein the flexible film includes an interconnection layer for electrically coupling the backplane of the plurality of light-emitting device units.

15. A method for producing a micro-LED ultraviolet radiation source, comprising:
providing a multilayer stack which includes
a crystal growth substrate,
a frontplane supported by the crystal growth substrate, the frontplane including a plurality of micro-LEDs, each of which includes a first semiconductor layer of a first conductivity type and a second semiconductor layer of a second conductivity type and is capable of radiating ultraviolet light, and a device isolation region located between the plurality of micro-LEDs, the device isolation region including at least one metal plug electrically coupled with the second semiconductor layer, and
a middle layer supported by the frontplane, the middle layer including a plurality of first contact electrodes respectively electrically coupled with the first semiconductor layer of the plurality of micro-LEDs and at least one second contact electrode coupled with the metal plug;
forming a backplane on the multilayer stack, the backplane including an electric circuit electrically coupled with the plurality of micro-LEDs via the plurality of first contact electrodes and the at least one second contact electrode;
dividing the multilayer stack and the backplane into a plurality of light-emitting device units; and
transferring the plurality of light-emitting device units to a flexible film.

16. The method of claim 15, wherein the transferring includes
attaching an expandable film to the crystal growth substrate and expanding the expandable film, thereby enlarging a gap between the plurality of light-emitting device units, and
attaching the plurality of light-emitting device units on the expanded expandable film to the flexible film.

17. The method of claim 15, wherein the transferring includes
attaching an expandable film to the backplane and expanding the expandable film, thereby enlarging a gap between the plurality of light-emitting device units, and
further attaching the expanded expandable film to a member having a curved surface or a corner portion while the plurality of light-emitting device units are kept attached to the expanded expandable film.
